(19) United States
(12) Patent Application Publication
(10) Pub. No.: US 2026/0079550 A1
(43) Pub. Date: Mar. 19, 2026

(54) POWER MUX CIRCUITRY FOR SUPPLY RAIL SWITCHING

(71) Applicants: Arvind RAMAN, Austin, TX (US); Abdullah AFZAL, Austin, TX (US); Robbie TOMASZEWSKI, Cedar Park, TX (US); Manjith KUMAR, Portland, OR (US); David PAWLOWSKI, Portland, OR (US); Viral THAKER, Portland, OR (US); Ahmed Mohamed YOUSSEF, Tigard, OR (US); Dana COFFMAN, Portland, OR (US)

(72) Inventors: Arvind RAMAN, Austin, TX (US); Abdullah AFZAL, Austin, TX (US); Robbie TOMASZEWSKI, Cedar Park, TX (US); Manjith KUMAR, Portland, OR (US); David PAWLOWSKI, Portland, OR (US); Viral THAKER, Portland, OR (US); Ahmed Mohamed YOUSSEF, Tigard, OR (US); Dana COFFMAN, Portland, OR (US)

(21) Appl. No.: 18/982,969

(22) Filed: Dec. 16, 2024

Related U.S. Application Data
(60) Provisional application No. 63/696,769, filed on Sep. 19, 2024.

(51) Int. Cl. G06F 1/26; H03K 17/00

(52) U.S. Cl. CPC G06F 1/263; H03K 17/002

(57) ABSTRACT

A power multiplexer (mux) circuit to switch between core and memory power supply rails. The power mux includes controllable variable resistance legs to adjust supply switch path resistances, for example, based on differences between the core and supply voltage rails.

### CROSS-REFERENCE TO RELATED APPLICATION

The present application claims the benefit of U.S. Provisional Application No. 63/696,769, filed Sep. 19, 2024, which is hereby incorporated by reference.

### TECHNICAL FIELD

Embodiments relate to the field of semiconductor devices; and more specifically to the area of supplying power to circuits in semiconductor.

### BRIEF DESCRIPTION OF THE DRAWINGS

The disclosure may best be understood by referring to the following description and accompanying drawings that are used to illustrate embodiments of the invention. In the drawings:

FIG. 1 is a block diagram of an example processor and/or System on a Chip (SoC) with one or more cores including a power multiplexer circuit.

FIG. 2 is a diagram showing a core with power mux circuitry.

FIG. 3A is a diagram showing a power mux circuit.

FIG. 3B is a diagram showing a resistor ladder circuit.

FIG. 4 is a flow diagram showing a routine for controlling a PMux circuit to transition between supply rails.

FIG. 5 is a flow diagram showing a routine for entering a core into a reduced power mode.

FIG. 6 illustrates an example computing system.

FIG. 7 is a block diagram illustrating a computing system configured to implement one or more aspects of the examples described herein.

FIG. 8A illustrates examples of a parallel processor.

FIG. 8B illustrates examples of a block diagram of a partition unit.

FIG. 8C illustrates examples of a block diagram of a processing cluster within a parallel processing unit.

FIG. 8D illustrates examples of a graphics multiprocessor in which the graphics multiprocessor couples with the pipeline manager of the processing cluster.

FIGS. 9A-9C illustrate additional graphics multiprocessors, according to examples.

FIG. 10 shows a parallel compute system.

FIGS. 11A-11B illustrate a hybrid logical/physical view of a disaggregated parallel processor.

FIG. 12(A) is a block diagram illustrating both an example in-order pipeline and an example register renaming, out-of-order issue/execution pipeline.

FIG. 12(B) is a block diagram illustrating both an example in-order architecture core and an example register renaming, out-of-order issue/execution architecture core to be included in a processor.

FIG. 13 illustrates examples of execution unit(s) circuitry, such as execution unit(s) circuitry.

FIG. 14 is a block diagram of a register architecture.

FIG. 15 illustrates examples of an instruction format.

FIGS. 16A-16B illustrate thread execution logic including an array of processing elements employed in a graphics processor core.

FIG. 17 illustrates an additional execution unit.

FIG. 18 is a block diagram illustrating graphics processor instruction formats.

FIG. 19 is a block diagram of another example of a graphics processor.

FIG. 20A is a block diagram illustrating a graphics processor command format.

FIG. 20B is a block diagram illustrating a graphics processor command sequence.

FIG. 21 is a block diagram illustrating the use of a software instruction converter to convert binary instructions in a source ISA to binary instructions in a target ISA.

FIG. 22 is a block diagram illustrating an IP core development system that may be used to manufacture an integrated circuit to perform operations.

### DETAILED DESCRIPTION

With many processor designs, minimum operational voltage requirements for cache arrays (e.g., L2 cache array in a core or core cluster) are higher than those for the core logic at lower voltage/frequency operating points. For example, allowable minimum voltage gaps between cache array circuits and inner core logic can be more than 100 mV. At the same time, it can be convenient to supply the core and the cache arrays with the same power supply, e.g., for layout resource efficiencies. Also, large high-performance cores often times demand significantly larger L2 cache arrays which support an inner core L1 to L2 cache hit in a single clock cycle. This makes it even more desirable for the inner core and the L2 logic to be at the same voltage level with the same clock tree during normal operation, when possible, to avoid clock domain and voltage domain crossings. However, with the core logic tied to the same power rail as the cache and thus not being able to go below the cache minimum voltage level, power is wasted at lower operating points with the core logic running at higher than necessary voltage levels. In addition, when the core goes to sleep, the L2 cache is flushed to the next level of the memory hierarchy. During the flush, the inner core typically does not need to be powered but because it is on the same voltage rail as the L2 logic, there is wasted leakage power even if the core can be gated.

To avoid these inefficiencies, alternative approaches would be desired to provide a separate, independently controllable voltage supply for the cache, allowing for the use of separate voltage/frequency (V/F) curves between the different domains. In this way, as the core frequency is reduced with its voltage going below the min cache level, the cache voltage can remain higher because of the separate power delivery sources. Unfortunately, using conventional configurations with this approach can result in excessive circuit infrastructure being required to provide the second voltage source and to ensure that it suitably tracks the core power source.

Accordingly, in some embodiments, new approaches using power multiplexer (mux) circuits are provided to reliably switch between a first voltage source for core logic and a second voltage source for memory and/or other circuits. In some embodiments, such a power mux may be used to provide cache arrays with the core supply unless and until the core supply is to go below the minimum cache level, and if so, then the power mux switches to supply the cache array with a second (minimum cache voltage) supply. In some embodiments, another power mux may be used in a similar manner to provide cache control circuits with the core supply when the core is running but switch the control circuit over to the second voltage source to support cache activity, e.g., for snoop or flush operations, when the core is gated off.

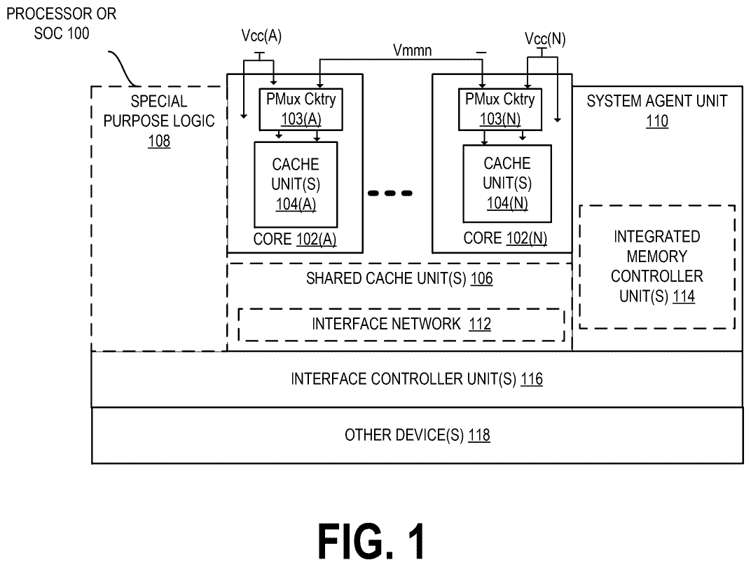

FIG. 1 illustrates a block diagram of an example processor and/or SoC 100 that may have one or more cores and an integrated memory controller. Shown is a processor and/or SoC 100 with multiple cores 102(A)-(N), a set of one or more integrated memory controller unit(s) circuitry 114 in system agent unit circuitry 110, and special purpose logic 108, as well as a set of one or more interface controller unit(s) circuits 116.

Thus, different implementations of the processor and/or SoC 100 may include: 1) a CPU with the special purpose logic 108 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like(which may include one or more cores, not shown), and the cores 102(A)-(N) being one or more general purpose cores (e.g., general purpose in-order cores, general purpose out-of-order cores, or a combination of the two); 2) a co-processor with the cores 102(A)-(N) being a large number of special purpose cores intended primarily for graphics and/or scientific (throughput); and 3) a co-processor with the cores 102(A)-(N) being a large number of general purpose in-order cores. Thus, the processor and/or SoC 100 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 100 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 104(A)-(N) within the cores 102(A)-(N), a set of one or more shared cache unit(s) circuitry 106, and external memory (not shown) coupled to the set of integrated memory controller unit(s) circuitry 114. The set of one or more shared cache unit(s) circuitry 106 may include one or more mid-level caches, such as level 2 (L2), level 3 (L3), level 4 (L4), or other levels of cache, such as a last level cache (LLC), and/or combinations thereof. While in some examples interface network circuitry 112 (e.g., a ring interconnect) interfaces the special purpose logic 108 (e.g., integrated graphics logic), the set of shared cache unit(s) circuitry 106, and the system agent unit circuitry 110, alternative examples use any number of well-known techniques for interfacing such units. In some examples, coherency is maintained between one or more of the shared cache unit(s) circuitry 106 and cores 102(A)-(N). In some examples, interface controller unit(s) circuitry 116 couple the cores 102(A)-(N) to one or more other devices 118 such as one or more I/O devices, storage, one or more communication devices (e.g., wireless networking, wired networking, etc.).

In some examples, one or more of the cores 102(A)-(N) are capable of multi-threading. The system agent unit circuitry 110 includes those components coordinating and operating cores 102(A)-(N). The system agent unit circuitry 110 may include, for example, power control unit (PCU) circuitry and/or display unit circuitry (not shown). The PCU may be or may include logic and components needed for regulating the power state of the cores 102(A)-(N) and/or the special purpose logic 108 (e.g., integrated graphics logic). The display unit circuitry is for driving one or more externally connected displays.

The cores 102(A)-(N) may be homogenous in terms of instruction set architecture (ISA). Alternatively, the cores 102(A)-(N) may be heterogeneous in terms of ISA; that is, a subset of the cores 102(A)-(N) may be capable of executing an ISA, while other cores may be capable of executing only a subset of that ISA or another ISA.

Some or all of the cores 102(A)-(N) may include power mux (PMux) circuits 103 to provide to circuit blocks within its associated core selected ones of a core supply (Vcc) or a minimum memory supply rail (Vmmn). In some embodiments, the core supplies (e.g., Vcc[A], Vcc[B], Vcc[N], etc.) are separately controllable for their associated core or core cluster, while the Vmmn supply may be a static voltage corresponding to a minimum operating voltage for a circuit block such as cache within the cores. For a given core, the core supply may be used for the core and memory loads together so long as the core supply is above the minimum memory block operating voltage but when the core voltage is to go below this level, one or more power mux switches may be used to switch the cache and/or other blocks such as cache control logic circuitry to the minimum memory supply (Vmmn). Note that the Vmmn rail may be static for given modes or specific devices, although it may be adjustable, from platform to platform or even within a platform, either statically or dynamically. For example, in some embodiments, the Vmmn supply rail may be fixed, based on fused or programmable (e.g., BIOS) settings, or it may be adjustable during processor operation. Note also that more than one min. memory supply may be provided, e.g., for different core memory groups and/or for different memory blocks.

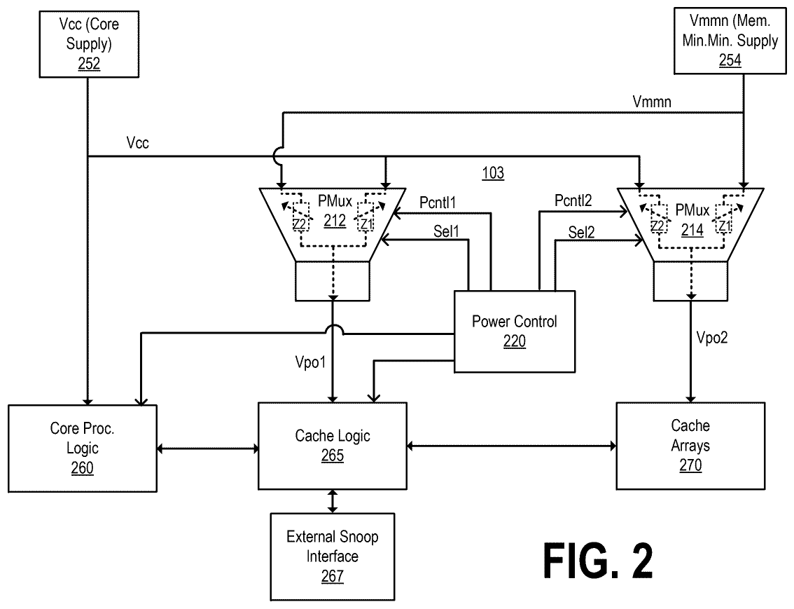

FIG. 2 is a diagram showing power mux circuit for a core circuit in accordance with some embodiments. The circuit includes core logic (e.g., inner core logic circuit) 260, cache control logic 265, and cache array(s) also referred to as cache or cache array circuit) 270 coupled together to facilitate processor core operations. In some embodiments, the cache arrays 270 and cache control logic 265 implement L2 cache, e.g., L2 data and tag SRAM arrays, with L1 cache being implemented as part of the core logic 260. There is also a snoop interface circuit 267 to provide access from outside of the core to the cache circuit 270 when core logic 260 is unavailable.

The circuit also includes a core supply (Vcc) rail 252, a minimum memory supply (Vmmn) rail 254, a first power mux circuit 212, a second power mux circuit 214, and a power control circuit 220, coupled together as shown. The power mux circuits 212, 214 each include controllable variable resistance legs (Z1, Z2) that are controllable by the power control circuit 220 through select (Sel1, Sel2) and power mux leg resistance control (Pcntl1, Pcntl2) signals as indicated. The first and second power muxes, 212, 214, are each coupled to the core and memory min supplies and are controlled by the power control circuit 220 to select one of them to be coupled through to their corresponding loads.

In the case of power mux 212, the output (Vpo1) is coupled to cache control logic 265, while the output (Vpo2) of power mux 214 is coupled to supply power to the cache array(s) 270. In some embodiments, the select signals (Sel1, Sel2) control which of the legs in a power mux (PMux) is selected, while the power control signals (Pcntl1, Pcntl2) control the resistances of either or both legs together. (Note that as used herein, a power mux circuit is a circuit with two or more supply rail legs, or paths, whose resistances may be controlled, to couple a selected one of the paths to an output of the power mux circuit.)

The cache arrays have a higher minimum voltage than the cache and core logic circuits. They can run together off of the same supply (Vcc) until the core is to go below the minimum cache level. When this is to occur, the power control circuit 220 switches PMux2 to supply the cache arrays 270 with Vmmn instead of Vcc. With the use of PMux circuits, this may occur seamlessly while the core and cache blocks continue to operate, albeit possibly in a stalled or throttling state.

The cache control logic 265 may still be powered from Vcc unless and until the core is to enter into a sleep mode, at which time, PMux1 may be switched to transfer supplied power to the cache logic 265 from Vcc to Vmmn. Under normal operation, the cache control logic 265 may operate at the same voltage as the core logic 260 and thus, PMux1 is normally controlled to couple Vcc to the cache control logic 265. However, in some implementations, the power control circuit 220, upon the core logic entering into a sleep mode, may transition PMux1 to the Vmmn voltage rail to couple the cache control logic 265 to the Vmmn supply to maintain any flush operations while simultaneously powering down the core and core supply Vcc. The use of a power mux in this manner can be beneficial, for example, where the core does not have a power gate and therefore would otherwise need to remain on until the flush is sufficiently completed. Even if there is a clock gate, it would likely have to be on for an excessive period to avoid problematic supply droops. On the other hand, with a power mux with controllably variable resistive legs, core logic supply may be turned off while smoothly transitioning the cache control logic 265 to the Vmmn supply. This reduces the leakage power of the inner core logic during the flush while also avoiding voltage or clock domain crossings between the cache logic and the core.

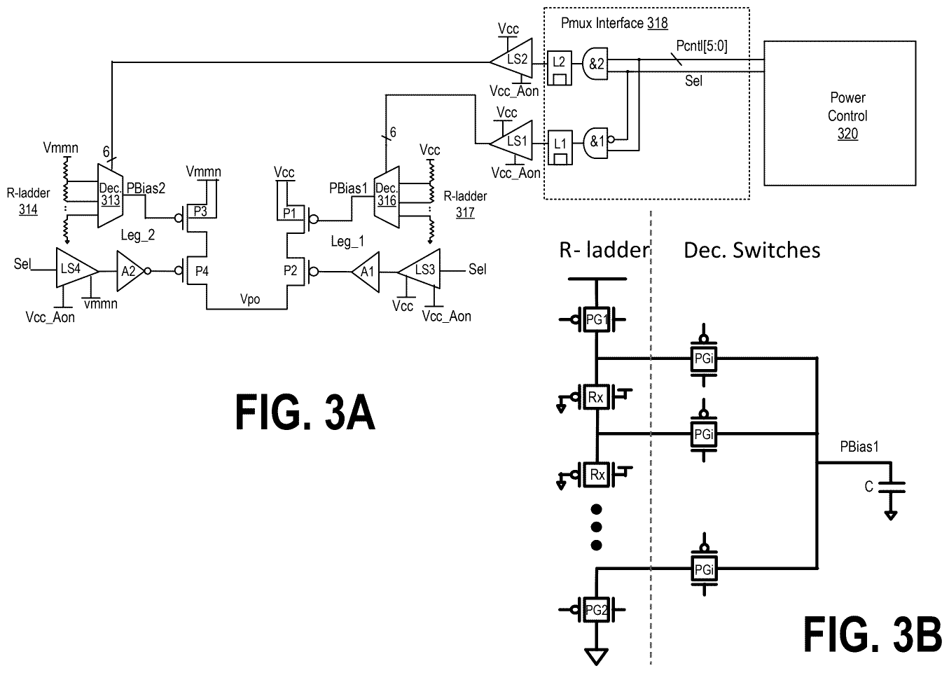

FIG. 3A is a diagram showing a power mux circuit in accordance with some embodiments. For example, the depicted power mux (PMux) circuit could be used to implement PMux circuits 212 or 214. The PMux circuit includes a first controllable, variable resistance leg (Leg_1), a second controllable, variable resistance leg (Leg_2) and an interface circuit 318. (For convenience, controllable, variable resistance legs may be referred to simply as a variable resistance leg, a controllable resistance leg, or as a resistance leg.)

The first variable resistance leg (Leg_1) includes P-type switch transistor(s) P2, buffer (A1), level shift circuit (LS3), variable resistance P-type transistor(s) (P1), decoder 316, resistor ladder circuit 317, and level shift circuit (LS2), coupled as shown. Similarly, the second variable resistance leg (Leg_2) includes P-type switch transistor(s) P4, inverting buffer (A2), level shift circuit (LS4), variable resistance P-type transistor(s) (P3), decoder 313, resistor ladder circuit 314, and level shift circuit (LS1), coupled as shown.

The PMux interface circuit 318 includes latch circuits (L1, L2) and gate circuits (&1, &2) configured to control operations of the first and second resistance legs through power control (Pcnt1) and select (Sel) signals from power control circuit 320. The And gates and latches are replicated (not shown) to accommodate the multi-bit Pcntl signal. In the depicted example, the Pcnt1 signal is a 6-bit digital value, so for each leg, a 6-bit latch enabled by the select signal could be used. The L1 latch and &1 gate control the value of the first resistor leg (Leg_1), while the L2 latch and &2 gate control the resistive value of the second resistor leg (Leg_2). The latch circuits may be used to hold the respective resistance legs a their last defined values when enabled by the select signal (Sel for Leg_2 and inverted Sel for Leg-1).

Among other things, the depicted circuit facilitates supply switch operations involving three different voltage supplies (Vcc, Vmmn, and Vcc_Aon). The Vcc supply is for core logic; the Vmmn is the minimum memory supply, and Vcc_Aon is a supply used by the power control circuit 320. Among other things, this configuration allows for multiple different combinations of supply voltage values, e.g., from design to design or version to version without having to re-design for different specific supplies. For example, some IP may be used in different products employing different control voltages (Vcc_Aon). With this example PMux circuit, the same circuit could be used for the different Vcc_Aon options.

In operation, the select signal selects one of the first and second legs to be coupled to the output (Vpo) through P2 and P4, respectively. That is, when Sel is Low, P2 turns on and Leg_1 is active, and when Sel is High, P4 turns on and Leg_2 is active. For each leg, based on the value of Pcntl, the associated decoder selects one of the output taps from the associated resistor ladder to apply a voltage level to an associated variable resistance transistor to control the resistance of the leg. For example, with the first leg (Leg_1), based on the 6-bit Pcnt1 code, decoder 316 couples a corresponding tap from resistor ladder 317 to the gate input of P1 to control its resistance. Note that with this configuration, since the value of Vcc may change depending on the operating and/or V/F state of the core, the voltages from the resistor ladder taps for R-ladder 317 may be different for a given tap selection, depending on the present value of Vcc. This may actually be beneficial, however, since with the use of a P-type variable resistance component, lower voltage levels will turn on the transistor more strongly, although these changes may be taken into account by the power control circuit so as to achieve a desired resistance level. Along these lines, instead of using Vcc as the supply for resistor ladder 317, the Vmmn supply, or other supplies, could be used for R-ladder 317, as well as for R-ladder 314. Note also that while with the depicted example, for ease of description, single transistors are shown for P1-P4, but in some embodiments, multiple transistors in parallel may be used to provide sufficient current sourcing operation for each transistor indicated in the diagram. Moreover, in some embodiments, instead of, or in addition to, the use of analog biased variable resistance devices (P1, P3), parallel-coupled switchable transistors could be used to provide the variable resistance in each PMux leg. In addition, it should be appreciated that while the switch transistors P2, P4 are controlled in the depicted example so that one is on at a time, in some embodiments, they may be independently controlled, for example, so that either one is on or both are turned off together.

FIG. 3B is a diagram showing a resistor ladder circuit in accordance with some embodiments. It includes resistors (Rx) formed from switched on P/N pass gates that are coupled together in series between P/N pass gate switches (PG1, PG2). The pass gate switches allow for the resistor ladder stack to be disabled so as not to waste power when a PMux is not operational. In some embodiments, they may be controlled by the power control circuit. The circuit also includes P/N passgate switches (PGi) to implement decoder switching for coupling a selected one of the resistor taps to an associated variable resistance device such as a P-type power transistor group.

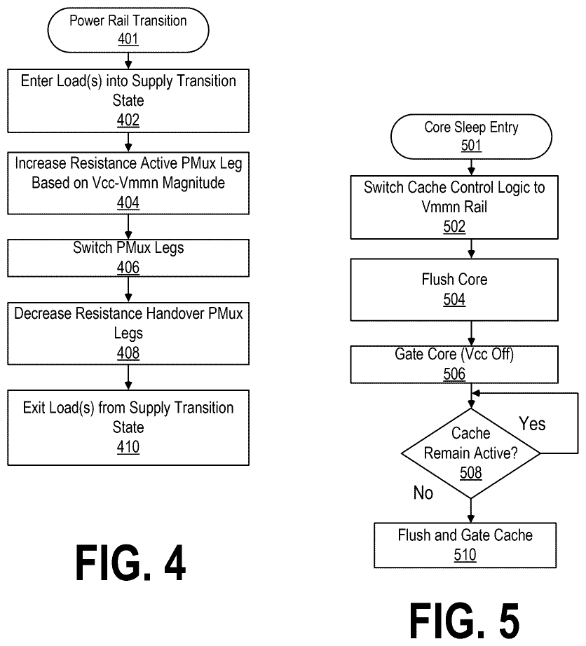

FIG. 4 is a flow diagram showing a routine 401 for controlling a PMux circuit to transition between supply rails in accordance with some embodiments. For example, this may be used for either PMux 212 or 214 to switch between Vcc and Vmmn supplies in a processor core. At 402, affected, or implicated, supply loads are entered into a supply transition state. For example, when switching cache or cache control logic either from Vmmn to Vcc or from Vcc to Vmmn, cache and snoop pipelines may be stalled or throttled, along with other clocks and/or core logic, while power mux switching is in progress. This may be helpful for guarding against noise, variations, and/or droops. In some embodiments, a power management flow to drain and quiesce logic blocks that support cache snoops may be triggered. A “stop interface” flow may also be triggered to temporarily halt incoming snoops to the core.

At 404, the resistance of the active PMux leg (the leg that is currently switched on) is raised, e.g., at a rate and to a level, based on the difference between Vcc and Vmmn. (Note that as used herein, the “active” leg refers to the leg that is presently active, and the “handover” leg refers to the leg that is to be activated.) In general, the higher the difference between the supplies when the switching is to occur, the higher the resistance may be elevated prior to actual leg switching. Depending on the PMux leg architecture, the resistances may be changed in any suitable manner. For example, transistor gate biases may be controlled, as with the example of FIG. 3A, or in addition to or alternatively, different combinations of switchable transistors making up part of the legs may be enabled to set a desired resistance.

Ideally, the PMux can be controlled to make the switch when the supplies are at the same, or substantially the same, voltages. In such cases, the active leg resistance, prior to switchover, need not be very high. However, there are situations, e.g., when switching from a core at its lowest voltage to the Vmmn supply such as when the core is to go to sleep, when the voltages cannot practically be equalized. In such cases, the active leg resistance should usually be raised to a higher level so as to avoid problematic spikes or excessive supply-to-supply currents. In situations when the supplies are the same, or close to the same, it is not necessarily critical that the handover leg (the leg that is to become active) is as high or at the same resistance as the active leg, although in some embodiments, it may be convenient, as well as operationally effective, to control the leg resistances in tandem to be at the same level regardless of the supply voltage difference. In cases where the supply differences are significant, it may be desirable to control the active and handover leg resistances to be at the same, sufficiently high, level when switchover actually takes place.

At 406, the legs are switched. For example, with respect to FIG. 3A, the select (Sel) signal transitions, e.g., to switch from Leg_1 to Leg_2 or from Leg_2 to Leg_1. At 408, the resistance of the handover leg is reduced, e.g., until maximum conductivity is reached. In some embodiments, the resistance may be ramped downward at a rate that avoids problematic noise and/or spikes. At 410, the affected load is switched out of the transition state, e.g., switched into a normal operational mode. For example, depending on what load supply was transitioned, PLL(s) may be restarted and snoop interface flow may be reenabled to receive incoming snoops to the core.

FIG. 5 is a flow diagram showing a routine 501 for entering a core into a reduced power (e.g., sleep) mode in accordance with some embodiments. At 502, cache control logic is switched to the Vmmn rail, e.g., in a manner consistent with the routine of FIG. 4. At 504, the core is then flushed. At 506, the core and core supply (Vcc) are turned off. At 508, it is determined if the cache is to remain active such as for snoop availability. If so, the routine loops back upon itself to 508, and the cache control logic and snoop interface remain functional, e.g., powered from the Vmmn supply. Otherwise, if the cache is not to remain active, then at 510, the cache is flushed, and the cache and cache control logic may be gated off.

### Example Architectures

Detailed below are descriptions of example computer architectures. Other system designs and configurations known in the arts for laptop, desktop, and handheld personal computers (PC)s, personal digital assistants, engineering workstations, servers, disaggregated servers, network devices, network hubs, switches, routers, embedded processors, digital signal processors (DSPs), graphics devices, video game devices, set-top boxes, micro controllers, cell phones, portable media players, hand-held devices, and various other electronic devices, are also suitable. In general, a variety of systems or electronic devices capable of incorporating a processor and/or other execution logic as disclosed herein are generally suitable. In some embodiments, the below examples may use power multiplexers to switch between supplies, e.g., for core logic, cache arrays and cache control logic, as described herein.

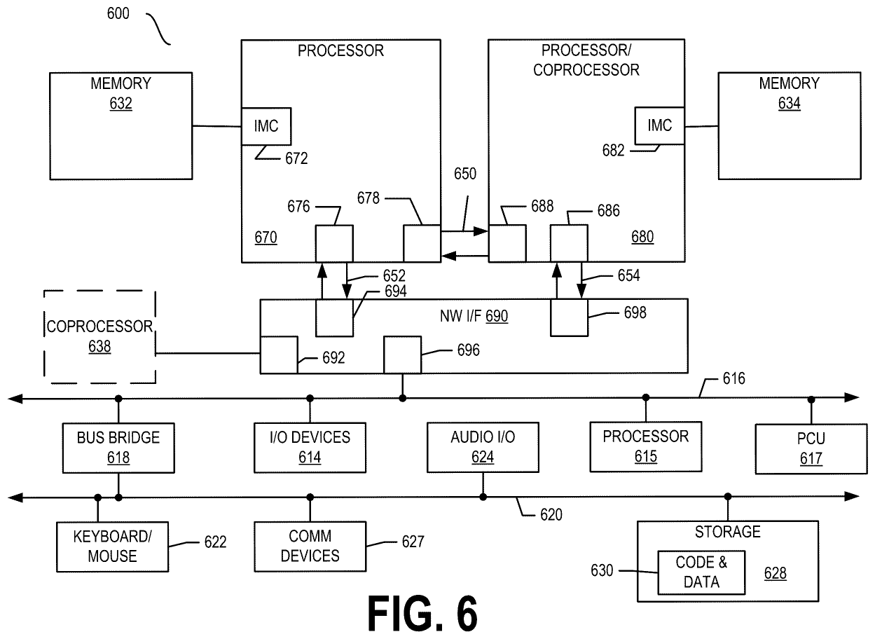

FIG. 6 illustrates an example computing system. Multiprocessor system 600 is an interfaced system and includes a plurality of processors or cores including a first processor 670 and a second processor 680 coupled via an interface 650 such as a point-to-point (P-P) interconnect, a fabric, and/or bus. In some examples, the first processor 670 and the second processor 680 are homogeneous. In some examples, first processor 670 and the second processor 680 are heterogenous. Though the example multiprocessor system 600 is shown to have two processors, the system may have three or more processors, or may be a single processor system. In some examples, the computing system is a system on a chip (SoC).

Processors 670 and 680 are shown including integrated memory controller (IMC) circuitry 672 and 682, respectively. Processor 670 also includes interface circuits 676 and 678; similarly, second processor 680 includes interface circuits 686 and 688. Processors 670, 680 may exchange information via the interface 650 using interface circuits 678, 688. IMCs 672 and 682 couple the processors 670, 680 to respective memories, namely a memory 632 and a memory 634, which may be portions of main memory locally attached to the respective processors.

Processors 670, 680 may each exchange information with a network interface (NW I/F) 690 via individual interfaces 652, 654 using interface circuits 676, 694, 686, 698. The network interface 690 (e.g., one or more of an interconnect, bus, and/or fabric, and in some examples is a chipset) may optionally exchange information with a co-processor 638 via an interface circuit 692. In some examples, the co-processor 638 is a special-purpose processor, such as, for example, a high-throughput processor, a network or communication processor, a compression engine, a graphics processor, a general purpose graphics processing unit (GPGPU), a neural-network processing unit (NPU), an embedded processor, a security processor, a cryptographic accelerator, a matrix accelerator, an in-memory analytics accelerator,, a data streaming accelerator, data graph operations, or the like.

A shared cache (not shown) may be included in either processor 670, 680 or outside of both processors, yet connected with the processors via an interface such as P-P interconnect, such that either or both processors'local cache information may be stored in the shared cache if a processor is placed into a low power mode.

Network interface 690 may be coupled to a first interface 616 via interface circuit 696. In some examples, first interface 616 may be an interface such as a Peripheral Component Interconnect (PCI) interconnect, a PCI Express interconnect or another I/O interconnect. In some examples, first interface 616 is coupled to a power control unit (PCU) 617, which may include circuitry, software, and/or firmware to perform power management operations with regard to the processors 670, 680 and/or co-processor 638. PCU 617 provides control information to a voltage regulator (not shown) to cause the voltage regulator to generate the appropriate regulated voltage. PCU 617 also provides control information to control the operating voltage generated. In various examples, PCU 617 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 617 is illustrated as being present as logic separate from the processor 670 and/or processor 680. In other cases, PCU 617 may execute on a given one or more of cores (not shown) of processor 670 or 680. In some cases, PCU 617 may be implemented as a microcontroller (dedicated or general-purpose) or other control logic configured to execute its own dedicated power management code, sometimes referred to as P-code. In yet other examples, power management operations to be performed by PCU 617 may be implemented externally to a processor, such as by way of a separate power management integrated circuit (PMIC) or another component external to the processor. In yet other examples, power management operations to be performed by PCU 617 may be implemented within BIOS or other system software.

Various I/O devices 614 may be coupled to first interface 616, along with a bus bridge 618 which couples first interface 616 to a second interface 620. In some examples, one or more additional processor(s) 615, such as co-processors, high throughput many integrated core (MIC) processors, GPGPUs, accelerators (such as graphics accelerators or digital signal processing (DSP) units), field programmable gate arrays (FPGAs), or any other processor, are coupled to first interface 616. In some examples, second interface 620 may be a low pin count (LPC) interface. Various devices may be coupled to second interface 620 including, for example, a keyboard and/or mouse 622, communication devices 627 and storage circuitry 628. Storage circuitry 628 may be one or more non-transitory machine-readable storage media as described below, such as a disk drive or other mass storage device which may include instructions/code and data 630 and may implement the storage 'ISAB03 in some examples. Further, an audio I/O 624 may be coupled to second interface 620. Note that other architectures than the point-to-point architecture described above are possible. For example, instead of the point-to-point architecture, a system such as multiprocessor system 600 may implement a multi-drop interface or other such architecture.

### Example Core Architectures, Processors, and Computer Architectures

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a co-processor including one or more special purpose cores intended primarily for graphics and/or scientific (throughput) computing. Such different processors lead to different computer system architectures, which may include: 1) the co-processor on a separate chip from the CPU; 2) the co-processor on a separate die in the same package as a CPU; 3) the co-processor on the same die as a CPU (in which case, such a co-processor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described co-processor, and additional functionality. Example core architectures are described next, followed by descriptions of example processors and computer architectures.

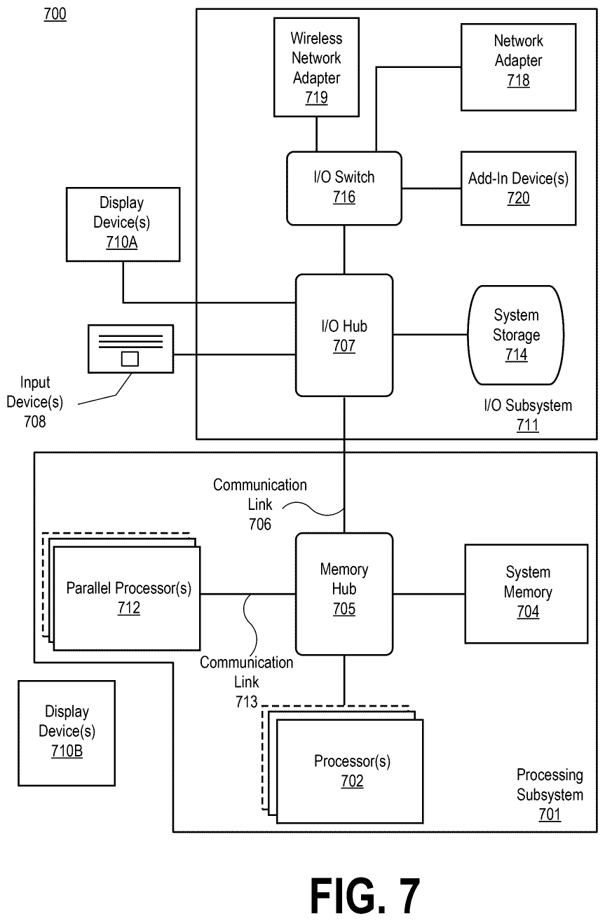

FIG. 7 is a block diagram illustrating a computing system 700 configured to implement one or more aspects of the examples described herein. The computing system 700 includes a processing subsystem 701 having one or more processor(s) 702 and a system memory 704 communicating via an interconnection path that may include a memory hub 705. The memory hub 705 may be a separate component within a chipset component or may be integrated within the one or more processor(s) 702. The memory hub 705 couples with an I/O subsystem 711 via a communication link 706. The I/O subsystem 711 includes an I/O hub 707 that can enable the computing system 700 to receive input from one or more input device(s) 708. Additionally, the I/O hub 707 can enable a display controller, which may be included in the one or more processor(s) 702, to provide outputs to one or more display device(s) 710A. In some examples the one or more display device(s) 710A coupled with the I/O hub 707 can include a local, internal, or embedded display device.

The processing subsystem 701, for example, includes one or more parallel processor(s) 712 coupled to memory hub 705 via a bus or communication link 713. The communication link 713 may be one of any number of standards-based communication link technologies or protocols, such as, but not limited to PCI Express, or may be a vendor specific communications interface or communications fabric. The one or more parallel processor(s) 712 may form a computationally focused parallel or vector processing system that can include a large number of processing cores and/or processing clusters, such as a many integrated core (MIC) processor. For example, the one or more parallel processor(s) 712 form a graphics processing subsystem that can output pixels to one of the one or more display device(s) 710A coupled via the I/O hub 707. The one or more parallel processor(s) 712 can also include a display controller and display interface (not shown) to enable a direct connection to one or more display device(s) 710B.

Within the I/O subsystem 711, a system storage unit 714 can connect to the I/O hub 707 to provide a storage mechanism for the computing system 700. An I/O switch 716 can be used to provide an interface mechanism to enable connections between the I/O hub 707 and other components, such as a network adapter 718 and/or wireless network adapter 719 that may be integrated into the platform, and various other devices that can be added via one or more add-in device(s) 720. The add-in device(s) 720 may also include, for example, one or more external graphics processor devices, graphics cards, and/or compute accelerators. The network adapter 718 can be an Ethernet adapter or another wired network adapter. The wireless network adapter 719 can include one or more of a Wi-Fi, Bluetooth, near field communication (NFC), or other network device that includes one or more wireless radios.

The computing system 700 can include other components not explicitly shown, including USB or other port connections, optical storage drives, video capture devices, and the like, which may also be connected to the I/O hub 707. Communication paths interconnecting the various components in FIG. 7 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 712 may incorporate circuitry optimized for graphics and video processing, including, for example, video output circuitry, and constitutes a graphics processing unit (GPU). Alternatively or additionally, the one or more parallel processor(s) 712 can incorporate circuitry optimized for general purpose processing, while preserving the underlying computational architecture, described in greater detail herein.

Components of the computing system 700 may be integrated with one or more other system elements on a single integrated circuit. For example, the one or more parallel processor(s) 712, memory hub 705, processor(s) 702, and I/O hub 707 can be integrated into a system on chip (SoC) integrated circuit. Alternatively, the components of the computing system 700 can be integrated into a single package to form a system in package (SIP) configuration. In some examples at least a portion of the components of the computing system 700 can be integrated into a multi-chip module (MCM), which can be interconnected with other multi-chip modules into a modular computing system.

It will be appreciated that the computing system 700 shown herein is illustrative and that variations and modifications are possible. The connection topology, including the number and arrangement of bridges, the number of processor(s) 702, and the number of parallel processor(s) 712, may be modified as desired. For instance, system memory 704 can be connected to the processor(s) 702 directly rather than through a bridge, while other devices communicate with system memory 704 via the memory hub 705 and the processor(s) 702. In other alternative topologies, the parallel processor(s) 712 are connected to the I/O hub 707 or directly to one of the one or more processor(s) 702, rather than to the memory hub 705. In other examples, the I/O hub 707 and memory hub 705 may be integrated into a single chip. It is also possible that two or more sets of processor(s) 702 are attached via multiple sockets, which can couple with two or more instances of the parallel processor(s) 712.

Some of the particular components shown herein are optional and may not be included in all implementations of the computing system 700. For example, any number of add-in cards or peripherals may be supported, or some components may be eliminated. Furthermore, some architectures may use different terminology for components similar to those illustrated in FIG. 7. For example, the memory hub 705 may be referred to as a Northbridge in some architectures, while the I/O hub 707 may be referred to as a Southbridge.

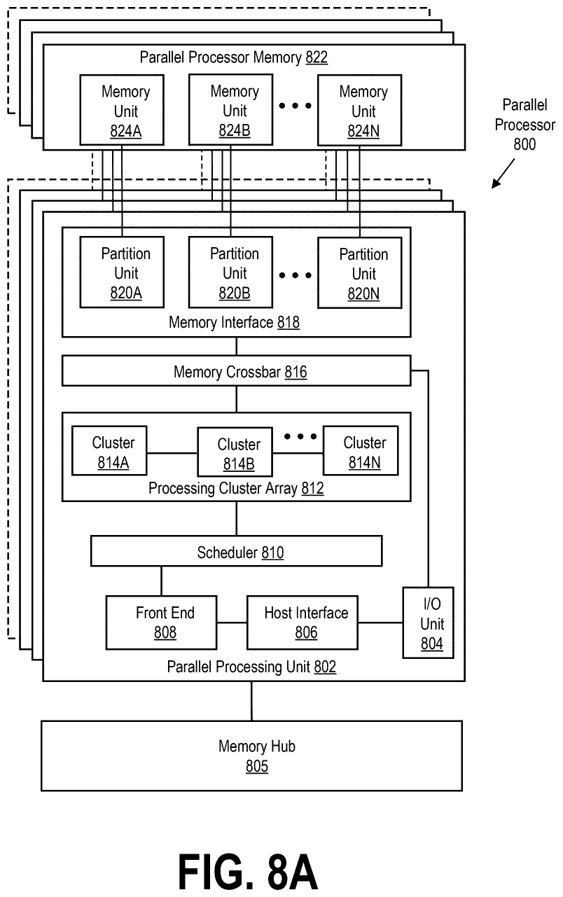

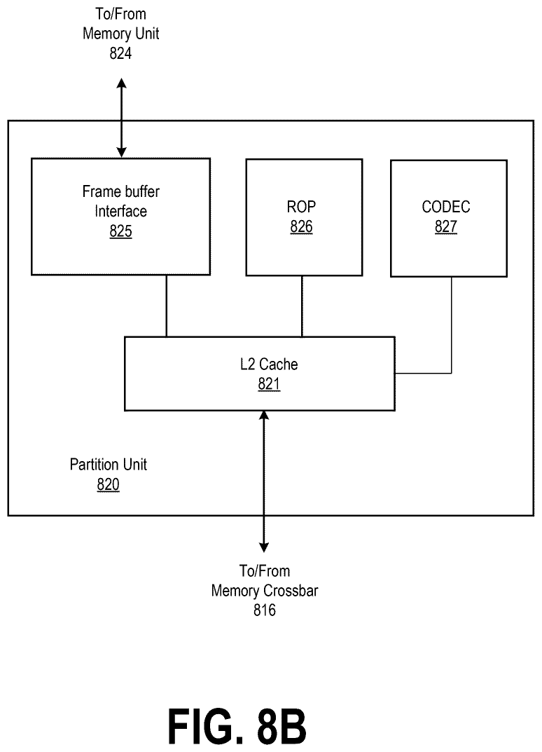

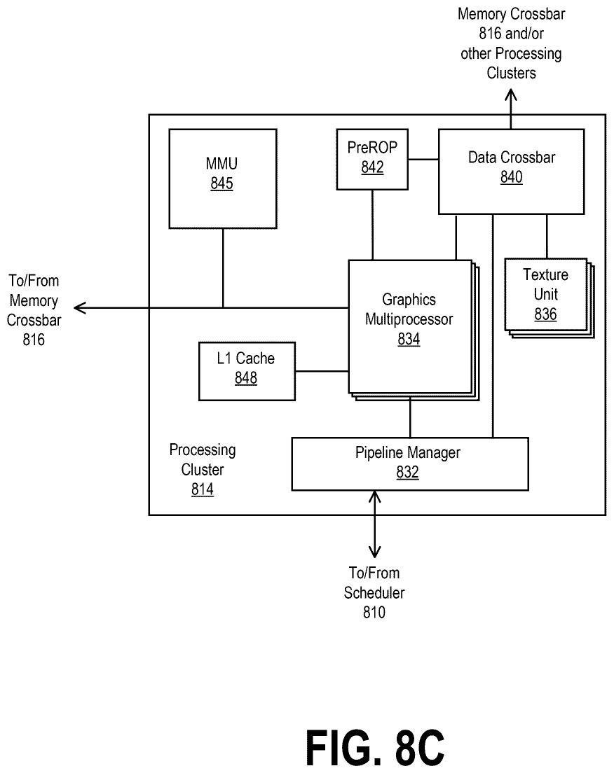

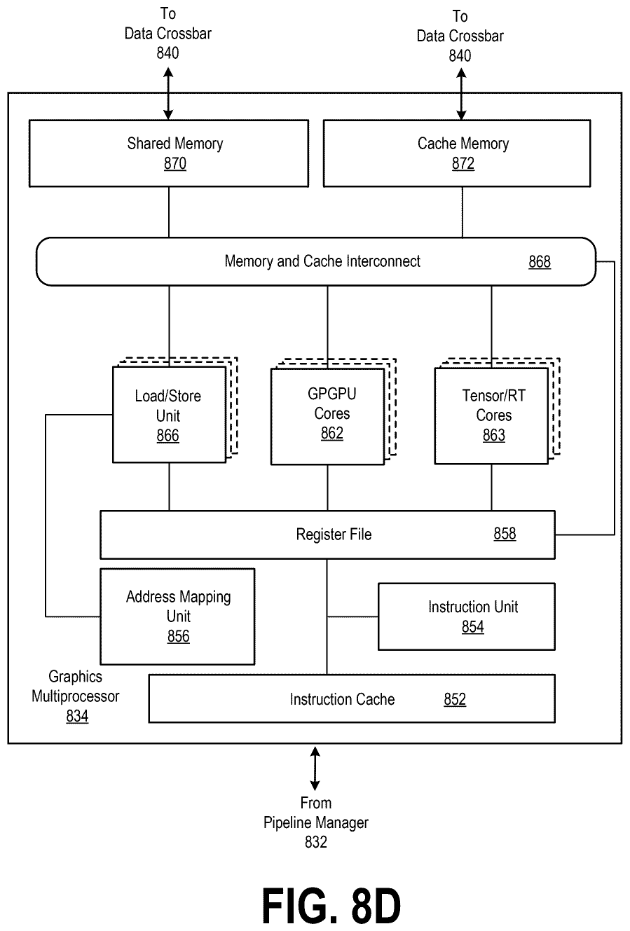

FIG. 8A illustrates examples of a parallel processor 800. The parallel processor 800 may be a GPU, GPGPU or the like as described herein. The various components of the parallel processor 800 may be implemented using one or more integrated circuit devices, such as programmable processors, application specific integrated circuits (ASICs), or field programmable gate arrays (FPGA). The parallel processor 800 may be one or more of the parallel processor(s) 712 shown in FIG. 7.

The parallel processor 800 includes a parallel processing unit 802. The parallel processing unit includes an I/O unit 804 that enables communication with other devices, including other instances of the parallel processing unit 802. The I/O unit 804 may be directly connected to other devices. For instance, the I/O unit 804 connects with other devices via the use of a hub or switch interface, such as memory hub 705. The connections between the memory hub 705 and the I/O unit 804 form a communication link 713. Within the parallel processing unit 802, the I/O unit 804 connects with a host interface 806 and a memory crossbar 816, where the host interface 806 receives commands directed to performing processing operations and the memory crossbar 816 receives commands directed to performing memory operations.

When the host interface 806 receives a command buffer via the I/O unit 804, the host interface 806 can direct work operations to perform those commands to a front end 808. In some examples the front end 808 couples with a scheduler 810, which is configured to distribute commands or other work items to a processing cluster array 812. The scheduler 810 ensures that the processing cluster array 812 is properly configured and in a valid state before tasks are distributed to the processing clusters of the processing cluster array 812. The scheduler 810 may be implemented via firmware logic executing on a microcontroller. The microcontroller implemented scheduler 810 is configurable to perform complex scheduling and work distribution operations at coarse and fine granularity, enabling rapid preemption and context switching of threads executing on the processing cluster array 812. Preferably, the host software can prove workloads for scheduling on the processing cluster array 812 via one of multiple graphics processing doorbells. In other examples, polling for new workloads or interrupts can be used to identify or indicate availability of work to perform. The workloads can then be automatically distributed across the processing cluster array 812 by the scheduler 810 logic within the scheduler microcontroller.

The processing cluster array 812 can include up to “N” processing clusters (e.g., cluster 814A, cluster 814B, through cluster 814N). Each cluster 814A-814N of the processing cluster array 812 can execute a large number of concurrent threads. The scheduler 810 can allocate work to the clusters 814A-814N of the processing cluster array 812 using various scheduling and/or work distribution algorithms, which may vary depending on the workload arising for each type of program or computation. The scheduling can be handled dynamically by the scheduler 810 or can be assisted in part by compiler logic during compilation of program logic configured for execution by the processing cluster array 812. Optionally, different clusters 814A-814N of the processing cluster array 812 can be allocated for processing different types of programs or for performing different types of computations.

The processing cluster array 812 can be configured to perform various types of parallel processing operations. For example, the processing cluster array 812 is configured to perform general-purpose parallel compute operations. For example, the processing cluster array 812 can include logic to execute processing tasks including filtering of video and/or audio data, performing modeling operations, including physics operations, and performing data transformations.

The processing cluster array 812 is configured to perform parallel graphics processing operations. In such examples in which the parallel processor 800 is configured to perform graphics processing operations, the processing cluster array 812 can include additional logic to support the execution of such graphics processing operations, including, but not limited to texture sampling logic to perform texture operations, as well as tessellation logic and other vertex processing logic. Additionally, the processing cluster array 812 can be configured to execute graphics processing related shader programs such as, but not limited to vertex shaders, tessellation shaders, geometry shaders, and pixel shaders. The parallel processing unit 802 can transfer data from system memory via the I/O unit 804 for processing. During processing the transferred data can be stored to on-chip memory (e.g., parallel processor memory 822) during processing, then written back to system memory.

In examples in which the parallel processing unit 802 is used to perform graphics processing, the scheduler 810 may be configured to divide the processing workload into approximately equal sized tasks, to better enable distribution of the graphics processing operations to multiple clusters 814A-814N of the processing cluster array 812. In some of these examples, portions of the processing cluster array 812 can be configured to perform different types of processing. For example, a first portion may be configured to perform vertex shading and topology generation, a second portion may be configured to perform tessellation and geometry shading, and a third portion may be configured to perform pixel shading or other screen space operations, to produce a rendered image for display. Intermediate data produced by one or more of the clusters 814A-814N may be stored in buffers to allow the intermediate data to be transmitted between clusters 814A-814N for further processing.

During operation, the processing cluster array 812 can receive processing tasks to be executed via the scheduler 810, which receives commands defining processing tasks from front end 808. For graphics processing operations, processing tasks can include indices of data to be processed, e.g., surface (patch) data, primitive data, vertex data, and/or pixel data, as well as state parameters and commands defining how the data is to be processed (e.g., what program is to be executed). The scheduler 810 may be configured to fetch the indices corresponding to the tasks or may receive the indices from the front end 808. The front end 808 can be configured to ensure the processing cluster array 812 is configured to a valid state before the workload specified by incoming command buffers (e.g., batch-buffers, push buffers, etc.) is initiated.

Each of the one or more instances of the parallel processing unit 802 can couple with parallel processor memory 822. The parallel processor memory 822 can be accessed via the memory crossbar 816, which can receive memory requests from the processing cluster array 812 as well as the I/O unit 804. The memory crossbar 816 can access the parallel processor memory 822 via a memory interface 818. The memory interface 818 can include multiple partition units (e.g., partition unit 820A, partition unit 820B, through partition unit 820N) that can each couple to a portion (e.g., memory unit) of parallel processor memory 822. The number of partition units 820A-820N may be configured to be equal to the number of memory units, such that a first partition unit 820A has a corresponding first memory unit 824A, a second partition unit 820B has a corresponding second memory unit 824B, and an Nth partition unit 820N has a corresponding Nth memory unit 824N. In other examples, the number of partition units 820A-820N may not be equal to the number of memory devices.

The memory units 824A-824N can include various types of memory devices, including dynamic random-access memory (DRAM) or graphics random access memory, such as synchronous graphics random access memory (SGRAM), including graphics double data rate (GDDR) memory. Optionally, the memory units 824A-824N may also include 3D stacked memory, including but not limited to high bandwidth memory (HBM). Persons skilled in the art will appreciate that the specific implementation of the memory units 824A-824N can vary and can be selected from one of various conventional designs. Render targets, such as frame buffers or texture maps may be stored across the memory units 824A-824N, allowing partition units 820A-820N to write portions of each render target in parallel to efficiently use the available bandwidth of parallel processor memory 822. In some examples, a local instance of the parallel processor memory 822 may be excluded in favor of a unified memory design that utilizes system memory in conjunction with local cache memory.

Optionally, any one of the clusters 814A-814N of the processing cluster array 812 has the ability to process data that will be written to any of the memory units 824A-824N within parallel processor memory 822. The memory crossbar 816 can be configured to transfer the output of each cluster 814A-814N to any partition unit 820A-820N or to another cluster 814A-814N, which can perform additional processing operations on the output. Each cluster 814A-814N can communicate with the memory interface 818 through the memory crossbar 816 to read from or write to various external memory devices. In one of the examples with the memory crossbar 816 the memory crossbar 816 has a connection to the memory interface 818 to communicate with the I/O unit 804, as well as a connection to a local instance of the parallel processor memory 822, enabling the processing units within the different processing clusters 814A-814N to communicate with system memory or other memory that is not local to the parallel processing unit 802. Generally, the memory crossbar 816 may, for example, be able to use virtual channels to separate traffic streams between the clusters 814A-814N and the partition units 820A-820N.

While a single instance of the parallel processing unit 802 is illustrated within the parallel processor 800, any number of instances of the parallel processing unit 802 can be included. For example, multiple instances of the parallel processing unit 802 can be provided on a single add-in card, or multiple add-in cards can be interconnected. For example, the parallel processor 800 can be an add-in device, such as add-in device(s) 720 of FIG. 7, which may be a graphics card such as a discrete graphics card that includes one or more GPUs, one or more memory devices, and device-to-device or network or fabric interfaces. The different instances of the parallel processing unit 802 can be configured to inter-operate even if the different instances have different numbers of processing cores, different amounts of local parallel processor memory, and/or other configuration differences. Optionally, some instances of the parallel processing unit 802 can include higher precision floating point units relative to other instances. Systems incorporating one or more instances of the parallel processing unit 802 or the parallel processor 800 can be implemented in a variety of configurations and form factors, including but not limited to desktop, laptop, or handheld personal computers, servers, workstations, game consoles, and/or embedded systems. An orchestrator can form composite nodes for workload performance using one or more of: disaggregated processor resources, cache resources, memory resources, storage resources, and networking resources.

In some examples, the parallel processing unit 802 can be partitioned into multiple instances. Those multiple instances can be configured to execute workloads associated with different clients in an isolated manner, enabling a pre-determined quality of service to be provided for each client. For example, each cluster 814A-814N can be compartmentalized and isolated from other clusters, allowing the processing cluster array 812 to be divided into multiple compute partitions or instances. In such configuration, workloads that execute on an isolated partition are protected from faults or errors associated with a different workload that executes on a different partition. The partition units 820A-820N can be configured to enable a dedicated and/or isolated path to memory for the clusters 814A-814N associated with the respective compute partitions. This datapath isolation enables the compute resources within a partition can communicate with one or more assigned memory units 824A-824N without being subjected to inference by the activities of other partitions.

FIG. 8B is a block diagram of a partition unit 820. The partition unit 820 may be an instance of one of the partition units 820A-820N of FIG. 8A. As illustrated, the partition unit 820 includes an L2 cache 821, a frame buffer interface 825, and a ROP 826 (raster operations unit). The L2 cache 821 is a read/write cache that is configured to perform load and store operations received from the memory crossbar 816 and ROP 826. Read misses and urgent write-back requests are output by L2 cache 821 to frame buffer interface 825 for processing. Updates can also be sent to the frame buffer via the frame buffer interface 825 for processing. In some examples the frame buffer interface 825 interfaces with one of the memory units in parallel processor memory, such as the memory units 824A-824N of FIG. 8A (e.g., within parallel processor memory 822). The partition unit 820 may additionally or alternatively also interface with one of the memory units in parallel processor memory via a memory controller (not shown).

In graphics applications, the ROP 826 is a processing unit that performs raster operations such as stencil, z test, blending, and the like. The ROP 826 then outputs processed graphics data that is stored in graphics memory. In some examples the ROP 826 includes or couples with a CODEC 827 that includes compression logic to compress depth or color data that is written to memory or the L2 cache 821 and decompress depth or color data that is read from memory or the L2 cache 821. The compression logic can be lossless compression logic that makes use of one or more of multiple compression algorithms. The type of compression that is performed by the CODEC 827 can vary based on the statistical characteristics of the data to be compressed. For example, in some examples, delta color compression is performed on depth and color data on a per-tile basis. In some examples the CODEC 827 includes compression and decompression logic that can compress and decompress compute data associated with machine learning operations. The CODEC 827 can, for example, compress sparse matrix data for sparse machine learning operations. The CODEC 827 can also compress sparse matrix data that is encoded in a sparse matrix format (e.g., coordinate list encoding (COO), compressed sparse row (CSR), compress sparse column (CSC), etc.) to generate compressed and encoded sparse matrix data. The compressed and encoded sparse matrix data can be decompressed and/or decoded before being processed by processing elements or the processing elements can be configured to consume compressed, encoded, or compressed and encoded data for processing.

The ROP 826 may be included within each processing cluster (e.g., cluster 814A-814N of FIG. 8A) instead of within the partition unit 820. In such example, read and write requests for pixel data are transmitted over the memory crossbar 816 instead of pixel fragment data. The processed graphics data may be displayed on a display device, such as one of the one or more display device(s) 710A-710B of FIG. 7, routed for further processing by the processor(s) 702, or routed for further processing by one of the processing entities within the parallel processor 800 of FIG. 8A.

FIG. 8C is a block diagram of a processing cluster 814 within a parallel processing unit. For example, the processing cluster is an instance of one of the processing clusters 814A-814N of FIG. 8A. The processing cluster 814 can be configured to execute many threads in parallel, where the term “thread” refers to an instance of a particular program executing on a particular set of input data. Optionally, single-instruction, multiple-data (SIMD) instruction issue techniques may be used to support parallel execution of a large number of threads without providing multiple independent instruction units. Alternatively, single-instruction, multiple-thread (SIMT) techniques may be used to support parallel execution of a large number of generally synchronized threads, using a common instruction unit configured to issue instructions to a set of processing engines within each one of the processing clusters. Unlike a SIMD execution regime, where all processing engines typically execute identical instructions, SIMT execution allows different threads to more readily follow divergent execution paths through a given thread program. Persons skilled in the art will understand that a SIMD processing regime represents a functional subset of a SIMT processing regime.

Operation of the processing cluster 814 can be controlled via a pipeline manager 832 that distributes processing tasks to SIMT parallel processors. The pipeline manager 832 receives instructions from the scheduler 810 of FIG. 8A and manages execution of those instructions via a graphics multiprocessor 834 and/or a texture unit 836. The graphics multiprocessor 834 is an exemplary instance of a SIMT parallel processor. However, various types of SIMT parallel processors of differing architectures may be included within the processing cluster 814. One or more instances of the graphics multiprocessor 834 can be included within a processing cluster 814. The graphics multiprocessor 834 can process data and a data crossbar 840 can be used to distribute the processed data to one of multiple possible destinations, including other shader units. The pipeline manager 832 can facilitate the distribution of processed data by specifying destinations for processed data to be distributed via the data crossbar 840.

Each graphics multiprocessor 834 within the processing cluster 814 can include an identical set of functional execution logic (e.g., arithmetic logic units, load-store units, etc.). The functional execution logic can be configured in a pipelined manner in which new instructions can be issued before previous instructions are complete. The functional execution logic supports a variety of operations including integer and floating-point arithmetic, comparison operations, Boolean operations, bit-shifting, and computation of various algebraic functions. The same functional-unit hardware could be leveraged to perform different operations and any combination of functional units may be present.

The instructions transmitted to the processing cluster 814 constitute a thread. A set of threads executing across the set of parallel processing engines is a thread group. A thread group executes the same program on different input data. Each thread within a thread group can be assigned to a different processing engine within a graphics multiprocessor 834. A thread group may include fewer threads than the number of processing engines within the graphics multiprocessor 834. When a thread group includes fewer threads than the number of processing engines, one or more of the processing engines may be idle during cycles in which that thread group is being processed. A thread group may also include more threads than the number of processing engines within the graphics multiprocessor 834. When the thread group includes more threads than the number of processing engines within the graphics multiprocessor 834, processing can be performed over consecutive clock cycles. Optionally, multiple thread groups can be executed concurrently on the graphics multiprocessor 834.

The graphics multiprocessor 834 may include an internal cache memory to perform load and store operations. Optionally, the graphics multiprocessor 834 can forego an internal cache and use a cache memory (e.g., level 1 (L1) cache 848) within the processing cluster 814. Each graphics multiprocessor 834 also has access to level 2 (L2) caches within the partition units (e.g., partition units 820A-820N of FIG. 8A) that are shared among all processing clusters 814 and may be used to transfer data between threads. The graphics multiprocessor 834 may also access off-chip global memory, which can include one or more of local parallel processor memory and/or system memory. Any memory external to the parallel processing unit 802 may be used as global memory. Embodiments in which the processing cluster 814 includes multiple instances of the graphics multiprocessor 834 can share common instructions and data, which may be stored in the L1 cache 848.

Each processing cluster 814 may include an MMU 845 (memory management unit) that is configured to map virtual addresses into physical addresses. In other examples, one or more instances of the MMU 845 may reside within the memory interface 818 of FIG. 8A. The MMU 845 includes a set of page table entries (PTEs) used to map a virtual address to a physical address of a tile and optionally a cache line index. The MMU 845 may include address translation lookaside buffers (TLB) or caches that may reside within the graphics multiprocessor 834 or the L1 cache 848 of processing cluster 814. The physical address is processed to distribute surface data access locality to allow efficient request interleaving among partition units. The cache line index may be used to determine whether a request for a cache line is a hit or miss.

In graphics and computing applications, a processing cluster 814 may be configured such that each graphics multiprocessor 834 is coupled to a texture unit 836 for performing texture mapping operations, e.g., determining texture sample positions, reading texture data, and filtering the texture data. Texture data is read from an internal texture L1 cache (not shown) or in some examples from the L1 cache within graphics multiprocessor 834 and is fetched from an L2 cache, local parallel processor memory, or system memory, as needed. Each graphics multiprocessor 834 outputs processed tasks to the data crossbar 840 to provide the processed task to another processing cluster 814 for further processing or to store the processed task in an L2 cache, local parallel processor memory, or system memory via the memory crossbar 816. A preROP 842 (pre-raster operations unit) is configured to receive data from graphics multiprocessor 834, direct data to ROP units, which may be located with partition units as described herein (e.g., partition units 820A-820N of FIG. 8A). The preROP 842 unit can perform optimizations for color blending, organize pixel color data, and perform address translations.

It will be appreciated that the core architecture described herein is illustrative and that variations and modifications are possible. Any number of processing units, e.g., graphics multiprocessor 834, texture units 836, preROPs 842, etc., may be included within a processing cluster 814. Further, while only one processing cluster 814 is shown, a parallel processing unit as described herein may include any number of instances of the processing cluster 814. Optionally, each processing cluster 814 can be configured to operate independently of other processing clusters 814 using separate and distinct processing units, L1 caches, L2 caches, etc.

FIG. 8D shows an example of the graphics multiprocessor 834 in which the graphics multiprocessor 834 couples with the pipeline manager 832 of the processing cluster 814. The graphics multiprocessor 834 has an execution pipeline including but not limited to an instruction cache 852, an instruction unit 854, an address mapping unit 856, a register file 858, one or more general purpose graphics processing unit (GPGPU) cores 862, and one or more load/store units 866. The GPGPU cores 862 and load/store units 866 are coupled with cache memory 872 and shared memory 870 via a memory and cache interconnect 868. The graphics multiprocessor 834 may additionally include tensor and/or ray-tracing cores 863 that include hardware logic to accelerate matrix and/or ray-tracing operations.

The instruction cache 852 may receive a stream of instructions to execute from the pipeline manager 832. The instructions are cached in the instruction cache 852 and dispatched for execution by the instruction unit 854. The instruction unit 854 can dispatch instructions as thread groups (e.g., warps), with each thread of the thread group assigned to a different execution unit within GPGPU core 862. An instruction can access any of a local, shared, or global address space by specifying an address within a unified address space. The address mapping unit 856 can be used to translate addresses in the unified address space into a distinct memory address that can be accessed by the load/store units 866.

The register file 858 provides a set of registers for the functional units of the graphics multiprocessor 834. The register file 858 provides temporary storage for operands connected to the data paths of the functional units (e.g., GPGPU cores 862, load/store units 866) of the graphics multiprocessor 834. The register file 858 may be divided between each of the functional units such that each functional unit is allocated a dedicated portion of the register file 858. For example, the register file 858 may be divided between the different warps being executed by the graphics multiprocessor 834.

The GPGPU cores 862 can each include floating point units (FPUs) and/or integer arithmetic logic units (ALUs) that are used to execute instructions of the graphics multiprocessor 834. In some implementations, the GPGPU cores 862 can include hardware logic that may otherwise reside within the tensor and/or ray-tracing cores 863. The GPGPU cores 862 can be similar in architecture or can differ in architecture. For example and in some examples, a first portion of the GPGPU cores 862 include a single precision FPU and an integer ALU while a second portion of the GPGPU cores include a double precision FPU. Optionally, the FPUs can implement the IEEE 754-2008 standard for floating point arithmetic or enable variable precision floating point arithmetic. The graphics multiprocessor 834 can additionally include one or more fixed function or special function units to perform specific functions such as copy rectangle or pixel blending operations. One or more of the GPGPU cores can also include fixed or special function logic.

The GPGPU cores 862 may include SIMD logic capable of performing a single instruction on multiple sets of data. Optionally, GPGPU cores 862 can physically execute SIMD4, SIMD8, and SIMD16 instructions and logically execute SIMD1, SIMD2, and SIMD32 instructions. The SIMD instructions for the GPGPU cores can be generated at compile time by a shader compiler or automatically generated when executing programs written and compiled for single program multiple data (SPMD) or SIMT architectures. Multiple threads of a program configured for the SIMT execution model can be executed via a single SIMD instruction. For example and in some examples, eight SIMT threads that perform the same or similar operations can be executed in parallel via a single SIMD8 logic unit.

The memory and cache interconnect 868 is an interconnect network that connects each of the functional units of the graphics multiprocessor 834 to the register file 858 and to the shared memory 870. For example, the memory and cache interconnect 868 is a crossbar interconnect that allows the load/store unit 866 to implement load and store operations between the shared memory 870 and the register file 858. The register file 858 can operate at the same frequency as the GPGPU cores 862, thus data transfer between the GPGPU cores 862 and the register file 858 is very low latency. The shared memory 870 can be used to enable communication between threads that execute on the functional units within the graphics multiprocessor 834. The cache memory 872 can be used as a data cache for example, to cache texture data communicated between the functional units and the texture unit 836. The shared memory 870 can also be used as a program managed cached. The shared memory 870 and the cache memory 872 can couple with the data crossbar 840 to enable communication with other components of the processing cluster. Threads executing on the GPGPU cores 862 can programmatically store data within the shared memory in addition to the automatically cached data that is stored within the cache memory 872.

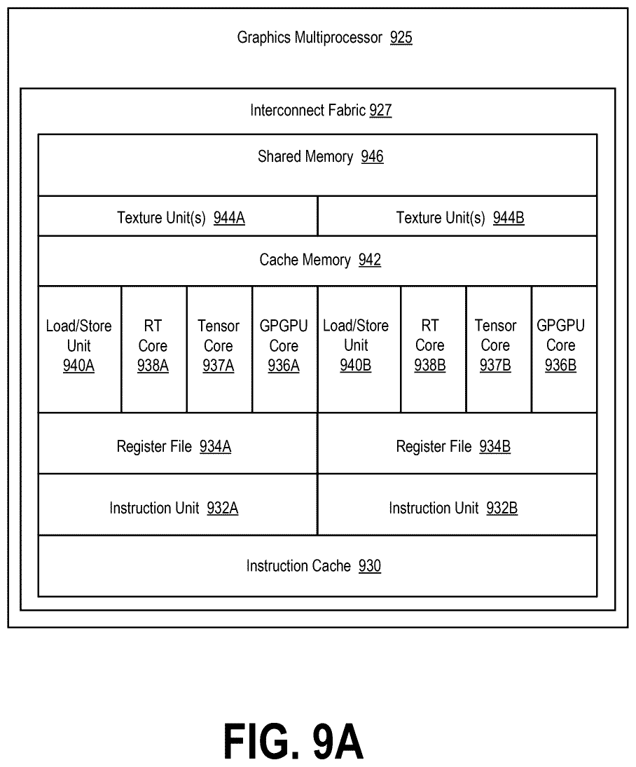

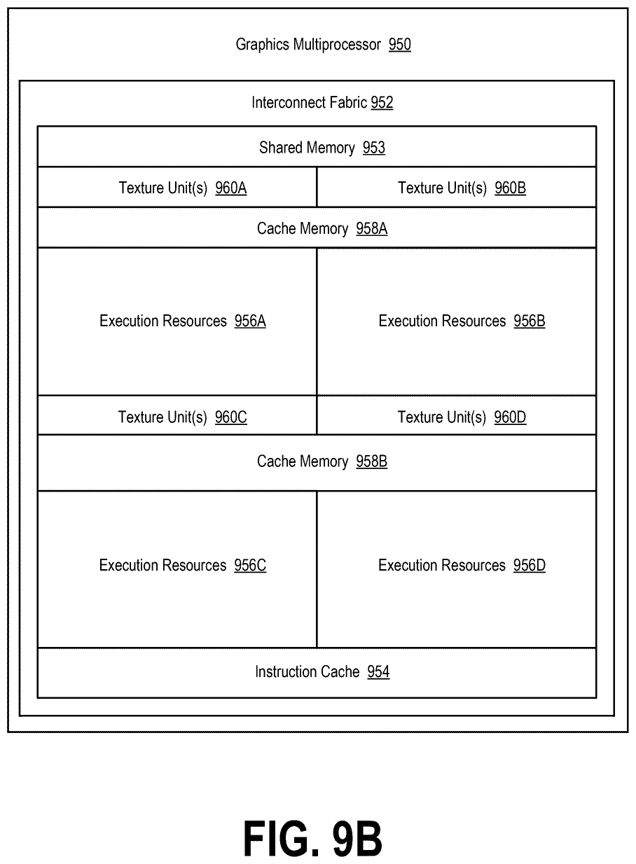

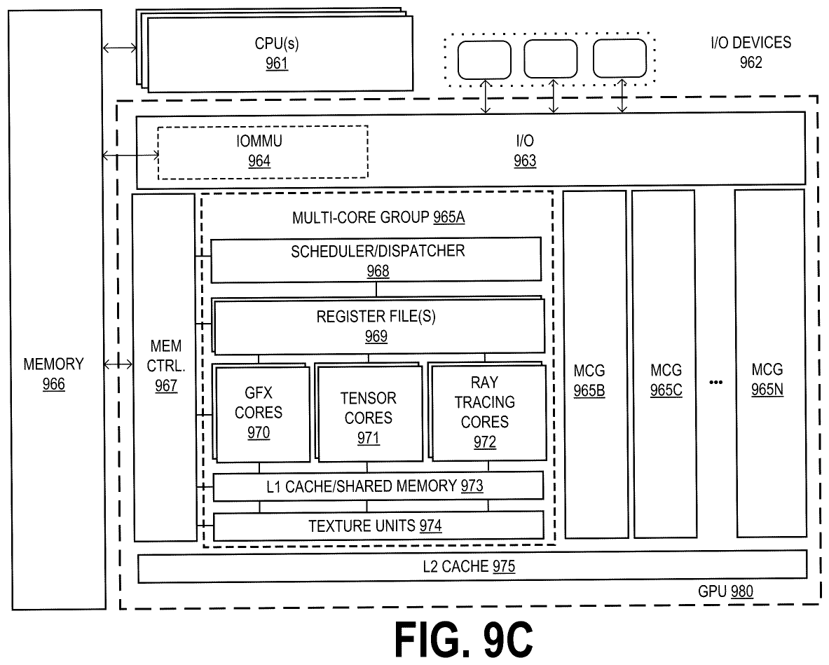

FIGS. 9A-9C illustrate additional graphics multiprocessors, according to examples. FIG. 9A-9B illustrate graphics multiprocessors 925, 950, which are related to the graphics multiprocessor 834 of FIG. 8C and may be used in place of one of those. Therefore, the disclosure of any features in combination with the graphics multiprocessor 834 herein also discloses a corresponding combination with the graphics multiprocessors 925, 950, but is not limited to such. FIG. 9C illustrates a graphics processing unit (GPU) 980 which includes dedicated sets of graphics processing resources arranged into multi-core groups 965A-965N, which correspond to the graphics multiprocessors 925, 950. The illustrated graphics multiprocessors 925, 950 and the multi-core groups 965A-965N can be streaming multiprocessors (SM) capable of simultaneous execution of a large number of execution threads.

The graphics multiprocessor 925 of FIG. 9A includes multiple additional instances of execution resource units relative to the graphics multiprocessor 834 of FIG. 8D. For example, the graphics multiprocessor 925 can include multiple instances of the instruction unit 932A-932B, register file 934A-934B, and texture unit(s) 944A-944B. The graphics multiprocessor 925 also includes multiple sets of graphics or compute execution units (e.g., GPGPU core 936A-936B, tensor core 937A-937B, ray-tracing core 938A-938B) and multiple sets of load/store units 940A-940B. The execution resource units have a common instruction cache 930, texture and/or data cache memory 942, and shared memory 946.

The various components can communicate via an interconnect fabric 927. The interconnect fabric 927 may include one or more crossbar switches to enable communication between the various components of the graphics multiprocessor 925. The interconnect fabric 927 may be a separate, high-speed network fabric layer upon which each component of the graphics multiprocessor 925 is stacked. The components of the graphics multiprocessor 925 communicate with remote components via the interconnect fabric 927. For example, the cores 936A-936B, 937A-937B, and 938A-938B can each communicate with shared memory 946 via the interconnect fabric 927. The interconnect fabric 927 can arbitrate communication within the graphics multiprocessor 925 to ensure a fair bandwidth allocation between components.

The graphics multiprocessor 950 of FIG. 9B includes multiple sets of execution resources 956A-956D, where each set of execution resource includes multiple instruction units, register files, GPGPU cores, and load store units, as illustrated in FIG. 8D and FIG. 9A. The execution resources 956A-956D can work in concert with texture unit(s) 960A-960D for texture operations, while sharing an instruction cache 954, and shared memory 953. For example, the execution resources 956A-956D can share an instruction cache 954 and shared memory 953, as well as multiple instances of a texture and/or data cache memory 958A-958B. The various components can communicate via an interconnect fabric 952 similar to the interconnect fabric 927 of FIG. 9A.

Persons skilled in the art will understand that the architecture described in FIG. 1, 8A-8D, and 9A-9B are descriptive and not limiting as to the scope of the present examples. Thus, the techniques described herein may be implemented on any properly configured processing unit, including, without limitation, one or more mobile application processors, one or more desktop or server central processing units (CPUs) including multi-core CPUs, one or more parallel processing units, such as the parallel processing unit 802 of FIG. 8A, as well as one or more graphics processors or special purpose processing units, without departure from the scope of the examples described herein.

The parallel processor or GPGPU as described herein may be communicatively coupled to host/processor cores to accelerate graphics operations, machine-learning operations, pattern analysis operations, and various general-purpose GPU (GPGPU) functions. The GPU may be communicatively coupled to the host processor/cores over a bus or other interconnect (e.g., a high-speed interconnect such as PCIe, NVLink, or other known protocols, standardized protocols, or proprietary protocols). In other examples, the GPU may be integrated on the same package or chip as the cores and communicatively coupled to the cores over an internal processor bus/interconnect (i.e., internal to the package or chip). Regardless of the manner in which the GPU is connected, the processor cores may allocate work to the GPU in the form of sequences of commands/instructions contained in a work descriptor. The GPU then uses dedicated circuitry/logic for efficiently processing these commands/instructions.

FIG. 9C illustrates a graphics processing unit (GPU) 980 which includes dedicated sets of graphics processing resources arranged into multi-core groups 965A-965N. While the details of only a single multi-core group 965A are provided, it will be appreciated that the other multi-core groups 965B-965N may be equipped with the same or similar sets of graphics processing resources. Details described with respect to the multi-core groups 965A-965N may also apply to any graphics multiprocessor 834, 925, 950 described herein.

As illustrated, a multi-core group 965A may include a set of graphics cores 970, a set of tensor cores 971, and a set of ray tracing cores 972. A scheduler/dispatcher 968 schedules and dispatches the graphics threads for execution on the various cores 970, 971, 972. A set of register files 969 store operand values used by the cores 970, 971, 972 when executing the graphics threads. These may include, for example, integer registers for storing integer values, floating point registers for storing floating point values, vector registers for storing packed data elements (integer and/or floating-point data elements) and tile registers for storing tensor/matrix values. The tile registers may be implemented as combined sets of vector registers.

One or more combined level 1 (L1) caches and shared memory units 973 store graphics data such as texture data, vertex data, pixel data, ray data, bounding volume data, etc., locally within each multi-core group 965A. One or more texture units 974 can also be used to perform texturing operations, such as texture mapping and sampling. A Level 2 (L2) cache 975 shared by all or a subset of the multi-core groups 965A-965N stores graphics data and/or instructions for multiple concurrent graphics threads. As illustrated, the L2 cache 975 may be shared across a plurality of multi-core groups 965A-965N. One or more memory controllers 967 couple the GPU 980 to a memory 966 which may be a system memory (e.g., DRAM) and/or a dedicated graphics memory (e.g., GDDR6 memory).

Input/output (I/O) circuitry 963 couples the GPU 980 to one or more I/O devices 962 such as digital signal processors (DSPs), network controllers, or user input devices. An on-chip interconnect may be used to couple the I/O devices 962 to the GPU 980 and memory 966. One or more I/O memory management units (IOMMUs) 964 of the I/O circuitry 963 couple the I/O devices 962 directly to the system memory 966. Optionally, the IOMMU 964 manages multiple sets of page tables to map virtual addresses to physical addresses in system memory 966. The I/O devices 962, CPU(s) 961, and GPU(s) 980 may then share the same virtual address space.

In one implementation of the IOMMU 964, the IOMMU 964 supports virtualization. In this case, it may manage a first set of page tables to map guest/graphics virtual addresses to guest/graphics physical addresses and a second set of page tables to map the guest/graphics physical addresses to system/host physical addresses (e.g., within system memory 966). The base addresses of each of the first and second sets of page tables may be stored in control registers and swapped out on a context switch (e.g., so that the new context is provided with access to the relevant set of page tables). While not illustrated in FIG. 9C, each of the cores 970, 971, 972 and/or multi-core groups 965A-965N may include translation lookaside buffers (TLBs) to cache guest virtual to guest physical translations, guest physical to host physical translations, and guest virtual to host physical translations.

The CPU(s) 961, GPUs 980, and I/O devices 962 may be integrated on a single semiconductor chip and/or chip package. The illustrated memory 966 may be integrated on the same chip or may be coupled to the memory controllers 967 via an off-chip interface. In one implementation, the memory 966 comprises GDDR6 memory which shares the same virtual address space as other physical system-level memories, although the underlying principles described herein are not limited to this specific implementation.

The tensor cores 971 may include a plurality of execution units specifically designed to perform matrix operations, which are the fundamental compute operation used to perform deep learning operations. For example, simultaneous matrix multiplication operations may be used for neural network training and inferencing. The tensor cores 971 may perform matrix processing using a variety of operand precisions including single precision floating-point (e.g., 32 bits), half-precision floating point (e.g., 16 bits), integer words (16 bits), bytes (8 bits), and half-bytes (4 bits). For example, a neural network implementation extracts features of each rendered scene, potentially combining details from multiple frames, to construct a high-quality final image.

In deep learning implementations, parallel matrix multiplication work may be scheduled for execution on the tensor cores 971. The training of neural networks, in particular, requires a significant number of matrix dot product operations. In order to process an inner-product formulation of an N×N×N matrix multiply, the tensor cores 971 may include at least N dot-product processing elements. Before the matrix multiply begins, one entire matrix is loaded into tile registers and at least one column of a second matrix is loaded each cycle for N cycles. Each cycle, there are N dot products that are processed.

Matrix elements may be stored at different precisions depending on the particular implementation, including 16-bit words, 8-bit bytes (e.g., INT8) and 4-bit half-bytes (e.g., INT4). Different precision modes may be specified for the tensor cores 971 to ensure that the most efficient precision is used for different workloads (e.g., such as inferencing workloads which can tolerate quantization to bytes and half-bytes). Supported formats additionally include 64-bit floating point (FP64) and non-IEEE floating point formats such as the bfloat16 format (e.g., Brain floating point), a 16-bit floating point format with one sign bit, eight exponent bits, and eight significand bits, of which seven are explicitly stored. One example includes support for a reduced precision tensor-float (TF32) mode, which performs computations using the range of FP32 (8-bits) and the precision of FP16 (10-bits). Reduced precision TF32 operations can be performed on FP32 inputs and produce FP32 outputs at higher performance relative to FP32 and increased precision relative to FP16. In some examples, one or more 8-bit floating point formats (FP8) are supported.

In some examples the tensor cores 971 support a sparse mode of operation for matrices in which the vast majority of values are zero. The tensor cores 971 include support for sparse input matrices that are encoded in a sparse matrix representation (e.g., coordinate list encoding (COO), compressed sparse row (CSR), compress sparse column (CSC), etc.). The tensor cores 971 also include support for compressed sparse matrix representations in the event that the sparse matrix representation may be further compressed. Compressed, encoded, and/or compressed and encoded matrix data, along with associated compression and/or encoding metadata, can be read by the tensor cores 971 and the non-zero values can be extracted. For example, for a given input matrix A, a non-zero value can be loaded from the compressed and/or encoded representation of at least a portion of matrix A. Based on the location in matrix A for the non-zero value, which may be determined from index or coordinate metadata associated with the non-zero value, a corresponding value in input matrix B may be loaded. Depending on the operation to be performed (e.g., multiply), the load of the value from input matrix B may be bypassed if the corresponding value is a zero value. In some examples, the pairings of values for certain operations, such as multiply operations, may be pre-scanned by scheduler logic and only operations between non-zero inputs are scheduled. Depending on the dimensions of matrix A and matrix B and the operation to be performed, output matrix C may be dense or sparse. Where output matrix C is sparse and depending on the configuration of the tensor cores 971, output matrix C may be output in a compressed format, a sparse encoding, or a compressed sparse encoding.

The ray tracing cores 972 may accelerate ray tracing operations for both real-time ray tracing and non-real-time ray tracing implementations. In particular, the ray tracing cores 972 may include ray traversal/intersection circuitry for performing ray traversal using bounding volume hierarchies (BVHs) and identifying intersections between rays and primitives enclosed within the BVH volumes. The ray tracing cores 972 may also include circuitry for performing depth testing and culling (e.g., using a Z buffer or similar arrangement). In one implementation, the ray tracing cores 972 perform traversal and intersection operations in concert with the image denoising techniques described herein, at least a portion of which may be executed on the tensor cores 971. For example, the tensor cores 971 may implement a deep learning neural network to perform denoising of frames generated by the ray tracing cores 972. However, the CPU(s) 961, graphics cores 970, and/or ray tracing cores 972 may also implement all or a portion of the denoising and/or deep learning algorithms.

In addition, as described above, a distributed approach to denoising may be employed in which the GPU 980 is in a computing device coupled to other computing devices over a network or high-speed interconnect. In this distributed approach, the interconnected computing devices may share neural network learning/training data to improve the speed with which the overall system learns to perform denoising for different types of image frames and/or different graphics applications.

The ray tracing cores 972 may process all BVH traversal and/or ray-primitive intersections, saving the graphics cores 970 from being overloaded with thousands of instructions per ray. For example, each ray tracing core 972 includes a first set of specialized circuitry for performing bounding box tests (e.g., for traversal operations) and/or a second set of specialized circuitry for performing the ray-triangle intersection tests (e.g., intersecting rays which have been traversed). Thus, for example, the multi-core group 965A can simply launch a ray probe, and the ray tracing cores 972 independently perform ray traversal and intersection and return hit data (e.g., a hit, no hit, multiple hits, etc.) to the thread context. The other cores 970, 971 are freed to perform other graphics or compute work while the ray tracing cores 972 perform the traversal and intersection operations.

Optionally, each ray tracing core 972 may include a traversal unit to perform BVH testing operations and/or an intersection unit which performs ray-primitive intersection tests. The intersection unit generates a “hit”, “no hit”, or “multiple hit” response, which it provides to the appropriate thread. During the traversal and intersection operations, the execution resources of the other cores (e.g., graphics cores 970 and tensor cores 971) are freed to perform other forms of graphics work.

In some examples described below, a hybrid rasterization/ray tracing approach is used in which work is distributed between the graphics cores 970 and ray tracing cores 972.

The ray tracing cores 972 (and/or other cores 970, 971) may include hardware support for a ray tracing instruction set such as Microsoft's DirectX Ray Tracing (DXR) which includes a DispatchRays command, as well as ray-generation, closest-hit, any-hit, and miss shaders, which enable the assignment of unique sets of shaders and textures for each object. Another ray tracing platform which may be supported by the ray tracing cores 972, graphics cores 970 and tensor cores 971 is Vulkan API (e.g., Vulkan version 1.1.85 and later). Note, however, that the underlying principles described herein are not limited to any particular ray tracing ISA.

In general, the various cores 972, 971, 970 may support a ray tracing instruction set that includes instructions/functions for one or more of ray generation, closest hit, any hit, ray-primitive intersection, per-primitive and hierarchical bounding box construction, miss, visit, and exceptions. More specifically, some examples includes ray tracing instructions to perform one or more of the following functions:

Ray Generation—Ray generation instructions may be executed for each pixel, sample, or other user-defined work assignment.

Closest Hit—A closest hit instruction may be executed to locate the closest intersection point of a ray with primitives within a scene.

Any Hit—An any hit instruction identifies multiple intersections between a ray and primitives within a scene, potentially to identify a new closest intersection point.

Intersection—An intersection instruction performs a ray-primitive intersection test and outputs a result.

Per-primitive Bounding box Construction—This instruction builds a bounding box around a given primitive or group of primitives (e.g., when building a new BVH or other acceleration data structure).

Miss—Indicates that a ray misses all geometry within a scene, or specified region of a scene.

Visit—Indicates the child volumes a ray will traverse.

Exceptions—Includes various types of exception handlers (e.g., invoked for various error conditions).

In some examples the ray tracing cores 972 may be adapted to accelerate general-purpose compute operations that can be accelerated using computational techniques that are analogous to ray intersection tests. A compute framework can be provided that enables shader programs to be compiled into low level instructions and/or primitives that perform general-purpose compute operations via the ray tracing cores. Exemplary computational problems that can benefit from compute operations performed on the ray tracing cores 972 include computations involving beam, wave, ray, or particle propagation within a coordinate space. Interactions associated with that propagation can be computed relative to a geometry or mesh within the coordinate space. For example, computations associated with electromagnetic signal propagation through an environment can be accelerated via the use of instructions or primitives that are executed via the ray tracing cores. Diffraction and reflection of the signals by objects in the environment can be computed as direct ray-tracing analogies.

Ray tracing cores 972 can also be used to perform computations that are not directly analogous to ray tracing. For example, mesh projection, mesh refinement, and volume sampling computations can be accelerated using the ray tracing cores 972. Generic coordinate space calculations, such as nearest neighbor calculations can also be performed. For example, the set of points near a given point can be discovered by defining a bounding box in the coordinate space around the point. BVH and ray probe logic within the ray tracing cores 972 can then be used to determine the set of point intersections within the bounding box. The intersections constitute the origin point and the nearest neighbors to that origin point. Computations that are performed using the ray tracing cores 972 can be performed in parallel with computations performed on the graphics cores 972 and tensor cores 971. A shader compiler can be configured to compile a compute shader or other general-purpose graphics processing program into low level primitives that can be parallelized across the graphics cores 970, tensor cores 971, and ray tracing cores 972.

Building larger and larger silicon dies is challenging for a variety of reasons. As silicon dies become larger, manufacturing yields become smaller and process technology requirements for different components may diverge. On the other hand, in order to have a high-performance system, key components should be interconnected by high speed, high bandwidth, low latency interfaces. These contradicting needs pose a challenge to high performance chip development.

Embodiments described herein provide techniques to disaggregate an architecture of a system on a chip integrated circuit into multiple distinct chiplets that can be packaged onto a common chassis. In some examples, a graphics processing unit or parallel processor is composed from diverse silicon chiplets that are separately manufactured. A chiplet is an at least partially packaged integrated circuit that includes distinct units of logic that can be assembled with other chiplets into a larger package. A diverse set of chiplets with different IP core logic can be assembled into a single device. Additionally the chiplets can be integrated into a base die or base chiplet using active interposer technology. The concepts described herein enable the interconnection and communication between the different forms of IP within the GPU. The development of IPs on different process may be mixed. This avoids the complexity of converging multiple IPs, especially on a large SoC with several flavors IPs, to the same process.

Enabling the use of multiple process technologies improves the time to market and provides a cost-effective way to create multiple product SKUs. For customers, this means getting products that are more tailored to their requirements in a cost effective and timely manner. Additionally, the disaggregated IPs are more amenable to being power gated independently, components that are not in use on a given workload can be powered off, reducing overall power consumption.

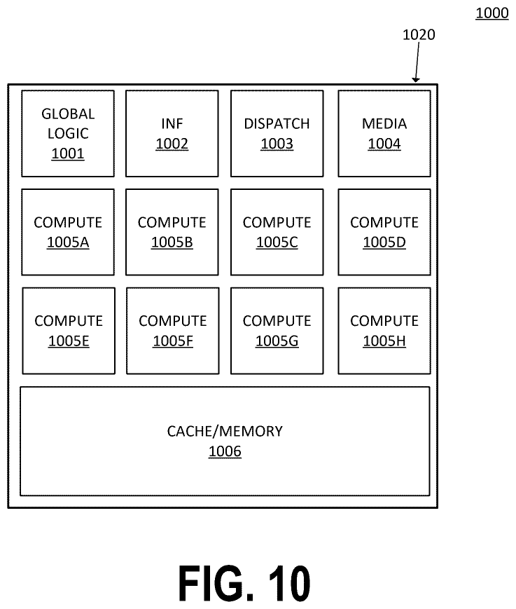

FIG. 10 shows a parallel compute system 1000, according to some examples. In some examples the parallel compute system 1000 includes a parallel processor 1020, which can be a graphics processor or compute accelerator as described herein. The parallel processor 1020 includes a global logic unit 1001, an interface 1002, a thread dispatcher 1003, a media unit 1004, a set of compute units 1005A-1005H, and a cache/memory units 1006. The global logic unit 1001, in some examples, includes global functionality for the parallel processor 1020, including device configuration registers, global schedulers, power management logic, and the like. The interface 1002 can include a front-end interface for the parallel processor 1020. The thread dispatcher 1003 can receive workloads from the interface 1002 and dispatch threads for the workload to the compute units 1005A-1005H. If the workload includes any media operations, at least a portion of those operations can be performed by the media unit 1004. The media unit can also offload some operations to the compute units 1005A-1005H. The cache/memory units 1006 can include cache memory (e.g., L3 cache) and local memory (e.g., HBM, GDDR) for the parallel processor 1020. Compute units 1005 may include units for one or more of a network or communication processor, a core, a graphics processor, a general purpose graphics processing unit (GPGPU), a neural-network processing unit (NPU), an embedded processor, a security processor, a cryptographic accelerator, a matrix accelerator, an in-memory analytics accelerator, a compression accelerator, a data streaming accelerator, or the like.

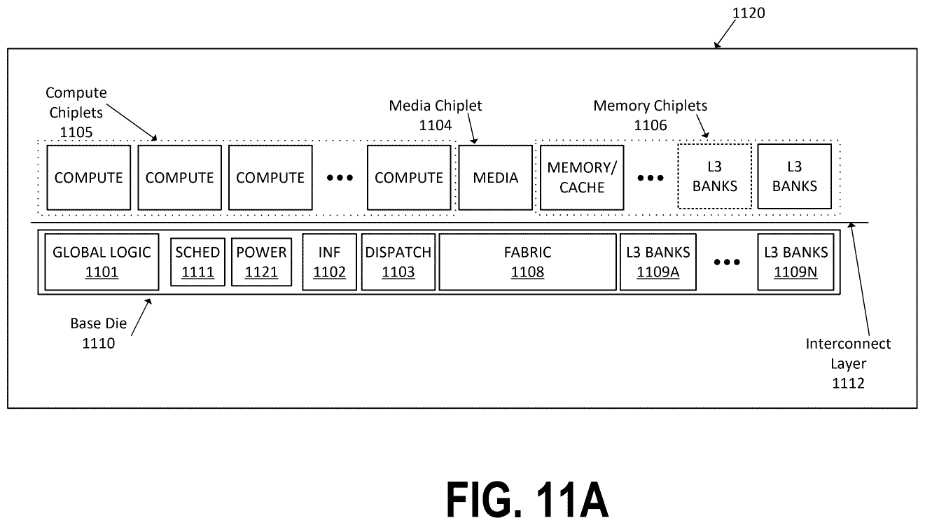

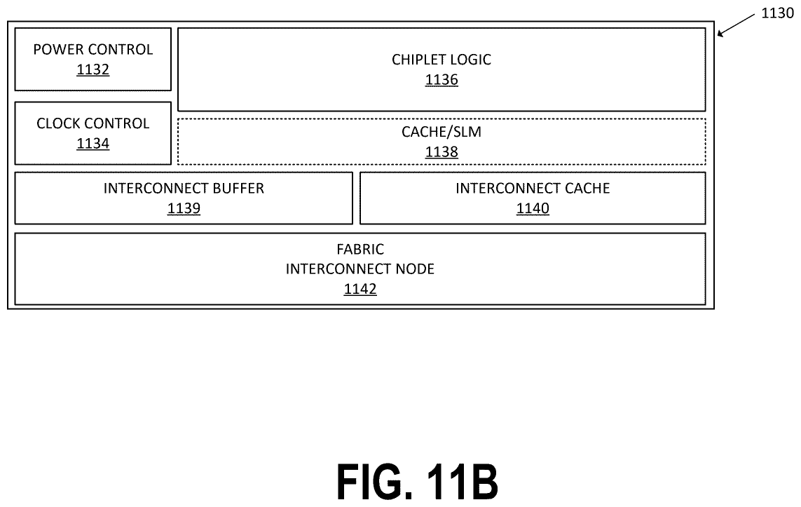

FIGS. 11A-11B illustrate a hybrid logical/physical view of a disaggregated parallel processor, according to examples described herein. FIG. 11A illustrates a disaggregated parallel compute system 1100. FIG. 11B illustrates a chiplet 1130 of the disaggregated parallel compute system 1100.

As shown in FIG. 11A, a disaggregated parallel compute system 1100 can include a parallel processor 1120 in which the various components of the parallel processor SOC are distributed across multiple chiplets. Each chiplet can be a distinct IP core that is independently designed and configured to communicate with other chiplets via one or more common interfaces. The chiplets include but are not limited to compute chiplets 1105, a media chiplet 1104, and memory chiplets 1106. Each chiplet can be separately manufactured using different process technologies. For example, compute chiplets 1105 may be manufactured using the smallest or most advanced process technology available at the time of fabrication, while memory chiplets 1106 or other chiplets (e.g., I/O, networking, etc.) may be manufactured using a larger or less advanced process technologies.

The various chiplets can be bonded to a base die 1110 and configured to communicate with each other and logic within the base die 1110 via an interconnect layer 1112. In some examples, the base die 1110 can include global logic 1101, which can include scheduler 1111 and power management 1121 logic units, an interface 1102, a dispatch unit 1103, and an interconnect fabric 1108 coupled with or integrated with one or more L3 cache banks 1109A-1109N. The interconnect fabric 1108 can be an inter-chiplet fabric that is integrated into the base die 1110. Logic chiplets can use the fabric 1108 to relay messages between the various chiplets. Additionally, L3 cache banks 1109A-1109N in the base die and/or L3 cache banks within the memory chiplets 1106 can cache data read from and transmitted to DRAM chiplets within the memory chiplets 1106 and to system memory of a host.

In some examples the global logic 1101 is a microcontroller that can execute firmware to perform scheduler 1111 and power management 1121 functionality for the parallel processor 1120. The microcontroller that executes the global logic can be tailored for the target use case of the parallel processor 1120. The scheduler 1111 can perform global scheduling operations for the parallel processor 1120. The power management 1121 functionality can be used to enable or disable individual chiplets within the parallel processor when those chiplets are not in use.

The various chiplets of the parallel processor 1120 can be designed to perform specific functionality that, in existing designs, would be integrated into a single die. A set of compute chiplets 1105 can include clusters of compute units (e.g., execution units, streaming multiprocessors, etc.) that include programmable logic to execute compute or graphics shader instructions. A media chiplet 1104 can include hardware logic to accelerate media encode and decode operations. Memory chiplets 1106 can include volatile memory (e.g., DRAM) and one or more SRAM cache memory banks (e.g., L3 banks).

As shown in FIG. 11B, each chiplet 1130 can include common components and application specific components. Chiplet logic 1136 within the chiplet 1130 can include the specific components of the chiplet, such as an array of streaming multiprocessors, compute units, or execution units described herein. The chiplet logic 1136 can couple with an optional cache or shared local memory 1138 or can include a cache or shared local memory within the chiplet logic 1136. The chiplet 1130 can include a fabric interconnect node 1142 that receives commands via the inter-chiplet fabric. Commands and data received via the fabric interconnect node 1142 can be stored temporarily within an interconnect buffer 1139. Data transmitted to and received from the fabric interconnect node 1142 can be stored in an interconnect cache 1140. Power control 1132 and clock control 1134 logic can also be included within the chiplet. The power control 1132 and clock control 1134 logic can receive configuration commands via the fabric can configure dynamic voltage and frequency scaling for the chiplet 1130. In some examples, each chiplet can have an independent clock domain and power domain and can be clock gated and power gated independently of other chiplets.

At least a portion of the components within the illustrated chiplet 1130 can also be included within logic embedded within the base die 1110 of FIG. 11A. For example, logic within the base die that communicates with the fabric can include a version of the fabric interconnect node 1142. Base die logic that can be independently clock or power gated can include a version of the power control 1132 and/or clock control 1134 logic.

Thus, while various examples described herein use the term SOC to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various examples of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems, the various dies, tiles, and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).”

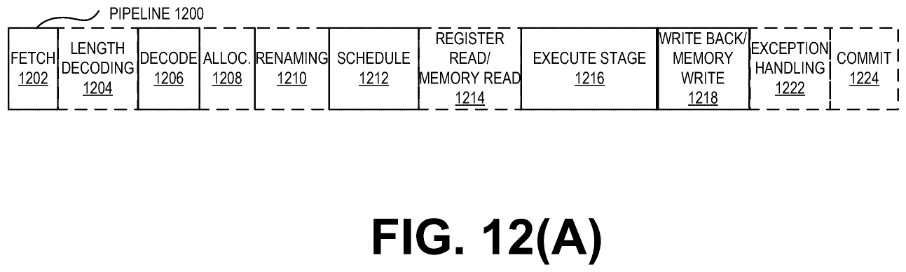

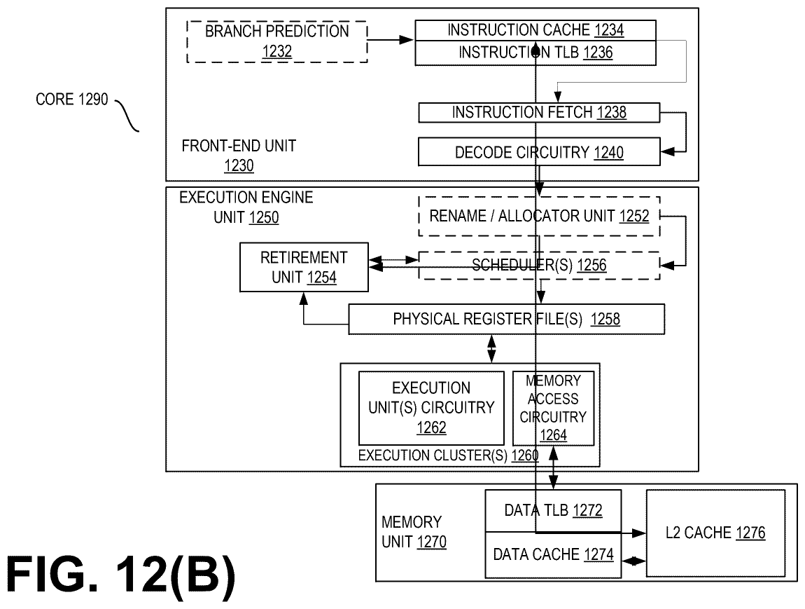

FIG. 12(A) is a block diagram illustrating both an example in-order pipeline and an example register renaming, out-of-order issue/execution pipeline according to examples. FIG. 12(B) is a block diagram illustrating both an example in-order architecture core and an example register renaming, out-of-order issue/execution architecture core to be included in a processor according to examples. The solid lined boxes in FIG. 12(A)-(B) illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 12(A), a processor pipeline 1200 includes a fetch stage 1202, an optional length decoding stage 1204, a decode stage 1206, an optional allocation (Alloc) stage 1208, an optional renaming stage 1210, a schedule (also known as a dispatch or issue) stage 1212, an optional register read/memory read stage 1214, an execute stage 1216, a write back/memory write stage 1218, an optional exception handling stage 1222, and an optional commit stage 1224. One or more operations can be performed in each of these processor pipeline stages. For example, during the fetch stage 1202, one or more instructions are fetched from instruction memory, and during the decode stage 1206, the one or more fetched instructions may be decoded, addresses (e.g., load store unit (LSU) addresses) using forwarded register ports may be generated, and branch forwarding (e.g., immediate offset or a link register (LR)) may be performed. In some examples, the decode stage 1206 and the register read/memory read stage 1214 may be combined into one pipeline stage. In some examples, during the execute stage 1216, the decoded instructions may be executed, LSU address/data pipelining to an Advanced Microcontroller Bus (AMB) interface may be performed, multiply and add operations may be performed, arithmetic operations with branch results may be performed, etc.

By way of example, the example register renaming, out-of-order issue/execution architecture core of FIG. 12(B) may implement the pipeline 1200 as follows: 1) the instruction fetch circuitry 1238 performs the fetch and length decoding stages 1202 and 1204; 2) the decode circuitry 1240 performs the decode stage 1206; 3) the rename/allocator unit circuitry 1252 performs the allocation stage 1208 and renaming stage 1210; 4) the scheduler(s) circuitry 1256 performs the schedule stage 1212; 5) the physical register file(s) circuitry 1258 and the memory unit circuitry 1270 perform the register read/memory read stage 1214; the execution cluster(s) 1260 perform the execute stage 1216; 6) the memory unit circuitry 1270 and the physical register file(s) circuitry 1258 perform the write back/memory write stage 1218; 7) various circuitry may be involved in the exception handling stage 1222; and 8) the retirement unit circuitry 1254 and the physical register file(s) circuitry 1258 perform the commit stage 1224.

FIG. 12(B) shows a processor core 1290 including front-end unit circuitry 1230 coupled to execution engine unit circuitry 1250, and both are coupled to memory unit circuitry 1270. The core 1290 may be a reduced instruction set architecture computing (RISC) core, a complex instruction set architecture computing (CISC) core, a very long instruction word (VLIW) core, or a hybrid or alternative core type. As yet another option, the core 1290 may be a special-purpose core, such as, for example, a network or communication core, compression engine, co-processor core, general purpose computing graphics processing unit (GPGPU) core, graphics core, or the like.

The front-end unit circuitry 1230 may include branch prediction circuitry 1232 coupled to instruction cache circuitry 1234, which is coupled to an instruction translation lookaside buffer (TLB) 1236, which is coupled to instruction fetch circuitry 1238, which is coupled to decode circuitry 1240. In some examples, the instruction cache circuitry 1234 is included in the memory unit circuitry 1270 rather than the front-end unit circuitry 1230. The decode circuitry 1240 (or decoder) may decode instructions, and generate as an output one or more micro-operations, micro-code entry points, microinstructions, other instructions, or other control signals, which are decoded from, or which otherwise reflect, or are derived from, the original instructions. The decode circuitry 1240 may further include address generation unit (AGU, not shown) circuitry. In some examples, the AGU generates an LSU address using forwarded register ports, and may further perform branch forwarding (e.g., immediate offset branch forwarding, LR register branch forwarding, etc.). The decode circuitry 1240 may be implemented using various different mechanisms. Examples of suitable mechanisms include, but are not limited to, look-up tables, hardware implementations, programmable logic arrays (PLAs), microcode read only memories (ROMs), etc. In some examples, the core 1290 includes a microcode ROM (not shown) or other medium that stores microcode for certain macroinstructions (e.g., in decode circuitry 1240 or otherwise within the front-end unit circuitry 1230). In some examples, the decode circuitry 1240 includes a micro-operation (micro-op) or operation cache (not shown) to hold/cache decoded operations, micro-tags, or micro-operations generated during the decode or other stages of the processor pipeline 1200. The decode circuitry 1240 may be coupled to rename/allocator unit circuitry 1252 in the execution engine unit circuitry 1250.

The execution engine unit circuitry 1250 includes the rename/allocator unit circuitry 1252 coupled to retirement unit circuitry 1254 and a set of one or more scheduler(s) circuitry 1256. The scheduler(s) circuitry 1256 represents any number of different schedulers, including reservations stations, central instruction window, etc. In some examples, the scheduler(s) circuitry 1256 can include arithmetic logic unit (ALU) scheduler/scheduling circuitry, ALU queues, address generation unit (AGU) scheduler/scheduling circuitry, AGU queues, etc. The scheduler(s) circuitry 1256 is coupled to the physical register file(s) circuitry 1258. Each of the physical register file(s) circuitry 1258 represents one or more physical register files, different ones of which store one or more different data types, such as scalar integer, scalar floating-point, packed integer, packed floating-point, vector integer, vector floating-point, status (e.g., an instruction pointer that is the address of the next instruction to be executed), etc. In some examples, the physical register file(s) circuitry 1258 includes vector registers unit circuitry, writemask registers unit circuitry, and scalar register unit circuitry. These register units may provide architectural vector registers, vector mask registers, general-purpose registers, etc. The physical register file(s) circuitry 1258 is coupled to the retirement unit circuitry 1254 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register maps and a pool of registers; etc.). The retirement unit circuitry 1254 and the physical register file(s) circuitry 1258 are coupled to the execution cluster(s) 1260. The execution cluster(s) 1260 includes a set of one or more execution unit(s) circuitry 1262 and a set of one or more memory access circuitry 1264. The execution unit(s) circuitry 1262 may perform various arithmetic, logic, floating-point or other types of operations (e.g., shifts, addition, subtraction, multiplication) and on various types of data (e.g., scalar integer, scalar floating-point, packed integer, packed floating-point, vector integer, vector floating-point). In some examples, execution unit(s) circuitry 1262 may include hardware to support functionality for instructions for one or more of a compression engine, graphics processing, neural-network processing, in-memory analytics, matrix operations, cryptographic operations, data streaming operations, data graph operations, etc.

While some examples may include a number of execution units or execution unit circuitry dedicated to specific functions or sets of functions, other examples may include only one execution unit circuitry or multiple execution units/execution unit circuitry that all perform all functions. The scheduler(s) circuitry 1256, physical register file(s) circuitry 1258, and execution cluster(s) 1260 are shown as being possibly plural because certain examples create separate pipelines for certain types of data/operations (e.g., a scalar integer pipeline, a scalar floating-point/packed integer/packed floating-point/vector integer/vector floating-point pipeline, and/or a memory access pipeline that each have their own scheduler circuitry, physical register file(s) circuitry, and/or execution cluster - and in the case of a separate memory access pipeline, certain examples are implemented in which only the execution cluster of this pipeline has the memory access unit(s) circuitry 1264). It should also be understood that where separate pipelines are used, one or more of these pipelines may be out-of-order issue/execution and the rest in-order.

In some examples, the execution engine unit circuitry 1250 may perform load store unit (LSU) address/data pipelining to an Advanced Microcontroller Bus (AMB) interface (not shown), and address phase and writeback, data phase load, store, and branches.

The set of memory access circuitry 1264 is coupled to the memory unit circuitry 1270, which includes data TLB circuitry 1272 coupled to data cache circuitry 1274 coupled to level 2 (L2) cache circuitry 1276. In some examples, the memory access circuitry 1264 may include load unit circuitry, store address unit circuitry, and store data unit circuitry, each of which is coupled to the data TLB circuitry 1272 in the memory unit circuitry 1270. The instruction cache circuitry 1234 is further coupled to the level 2 (L2) cache circuitry 1276 in the memory unit circuitry 1270. In some examples, the instruction cache 1234 and the data cache 1274 are combined into a single instruction and data cache (not shown) in L2 cache circuitry 1276, level 3 (L3) cache circuitry (not shown), and/or main memory. The L2 cache circuitry 1276 is coupled to one or more other levels of cache and eventually to a main memory.

The core 1290 may support one or more instructions sets (e.g., the x86 instruction set architecture (optionally with some extensions that have been added with newer versions); the MIPS instruction set architecture; the ARM instruction set architecture (optionally with optional additional extensions such as NEON, etc.); RISC instruction set architecture), including the instruction(s) described herein. In some examples, the core 1290 includes logic to support a packed data instruction set architecture extension (e.g., AVX1, AVX2, AVX512, AMX, etc.), thereby allowing the operations used by many multimedia applications to be performed using packed data.

### Example Execution Unit(s) Circuitry

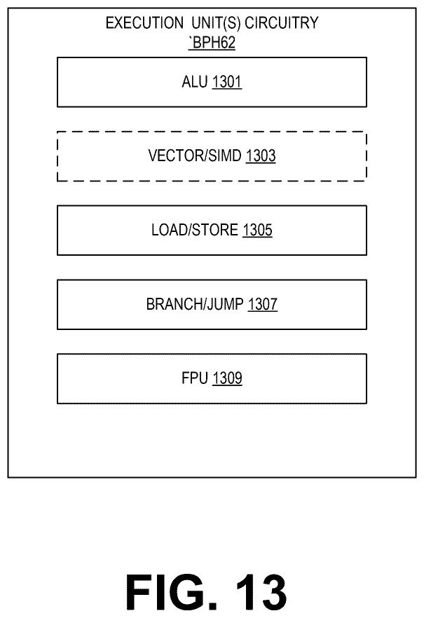

FIG. 13 illustrates examples of execution unit(s) circuitry, such as execution unit(s) circuitry 1262 of FIG. 12(B). As illustrated, execution unit(s) circuitry 1262 may include one or more ALU circuits 1301, optional vector/single instruction multiple data (SIMD) circuits 1303, load/store circuits 1305, branch/jump circuits 1307, and/or Floating-point unit (FPU) circuits 1309. ALU circuits 1301 perform integer arithmetic and/or Boolean operations. Vector/SIMD circuits 1303 perform vector/SIMD operations on packed data (such as SIMD/vector registers). Load/store circuits 1305 execute load and store instructions to load data from memory into registers or store from registers to memory. Load/store circuits 1305 may also generate addresses. Branch/jump circuits 1307 cause a branch or jump to a memory address depending on the instruction. FPU circuits 1309 perform floating-point arithmetic. The width of the execution unit(s) circuitry 1262 varies depending upon the example and can range from 16-bit to 1,024-bit, for example. In some examples, two or more smaller execution units are logically combined to form a larger execution unit (e.g., two 128-bit execution units are logically combined to form a 256-bit execution unit).

### Example Register Architecture

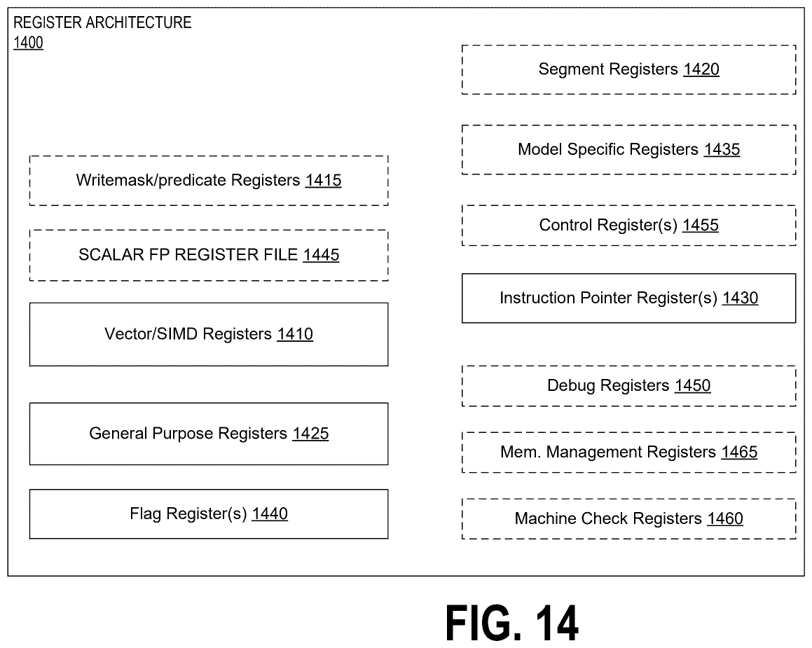

FIG. 14 is a block diagram of a register architecture 1400 according to some examples. As illustrated, the register architecture 1400 includes vector/SIMD registers 1410 that vary from 128-bit to 1,024 bits width. In some examples, the vector/SIMD registers 1410 are physically 512-bits and, depending upon the mapping, only some of the lower bits are used. For example, in some examples, the vector/SIMD registers 1410 are ZMM registers which are 512 bits: the lower 256 bits are used for YMM registers and the lower 128 bits are used for XMM registers. As such, there is an overlay of registers. In some examples, a vector length field selects between a maximum length and one or more other shorter lengths, where each such shorter length is half the length of the preceding length. Scalar operations are operations performed on the lowest order data element position in a ZMM/YMM/XMM register; the higher order data element positions are either left the same as they were prior to the instruction or zeroed depending on the example.

In some examples, the register architecture 1400 includes writemask/predicate registers 1415. For example, in some examples, there are 8 writemask/predicate registers (sometimes called k0 through k7) that are each 16-bit, 32-bit, 64-bit, or 128-bit in size. Writemask/predicate registers 1415 may allow for merging (e.g., allowing any set of elements in the destination to be protected from updates during the execution of any operation) and/or zeroing (e.g., zeroing vector masks allow any set of elements in the destination to be zeroed during the execution of any operation). In some examples, each data element position in a given writemask/predicate register 1415 corresponds to a data element position of the destination. In other examples, the writemask/predicate registers 1415 are scalable and consists of a set number of enable bits for a given vector element (e.g., 8 enable bits per 64-bit vector element).

The register architecture 1400 includes a plurality of general-purpose registers 1425. These registers may be 16-bit, 32-bit, 64-bit, etc. and can be used for scalar operations. In some examples, these registers are referenced by the names RAX, RBX, RCX, RDX, RBP, RSI, RDI, RSP, and R8 through R15.

In some examples, the register architecture 1400 includes scalar floating-point (FP) register file 1445 which is used for scalar floating-point operations on 32/64/80-bit floating-point data using the x87 instruction set architecture extension or as MMX registers to perform operations on 64-bit packed integer data, as well as to hold operands for some operations performed between the MMX and XMM registers.

One or more flag registers 1440 (e.g., EFLAGS, RFLAGS, etc.) store status and control information for arithmetic, compare, and system operations. For example, the one or more flag registers 1440 may store condition code information such as carry, parity, auxiliary carry, zero, sign, and overflow. In some examples, the one or more flag registers 1440 are called program status and control registers.

Segment registers 1420 contain segment points for use in accessing memory. In some examples, these registers are referenced by the names CS, DS, SS, ES, FS, and GS.

Model specific registers or machine specific registers (MSRs) 1435 control and report on processor performance. Most MSRs 1435 handle system-related functions and are not accessible to an application program. For example, MSRs may provide control for one or more of: performance-monitoring counters, debug extensions, memory type range registers, thermal and power management, instruction-specific support, and/or processor feature/mode support. Machine check registers 1460 consist of control, status, and error reporting MSRs that are used to detect and report on hardware errors. Control register(s) 1455 (e.g., CR0-CR4) determine the operating mode of a processor (e.g., processor 670, 680, 638, 615, and/or 100) and the characteristics of a currently executing task. In some examples, MSRs 1435 are a subset of control registers 1455.

One or more instruction pointer register(s) 1430 store an instruction pointer value. Debug registers 1450 control and allow for the monitoring of a processor or core's debugging operations.

Memory (mem) management registers 1465 specify the locations of data structures used in protected mode memory management. These registers may include a global descriptor table register (GDTR), interrupt descriptor table register (IDTR), task register, and a local descriptor table register (LDTR) register.

Alternative examples may use wider or narrower registers. Additionally, alternative examples may use more, less, or different register files and registers. The register architecture 1400 may, for example, be used in register file/memory 'ISAB08, or physical register file(s) circuitry 1258.

### Instruction Set Architectures

An instruction set architecture (ISA) may include one or more instruction formats. A given instruction format may define various fields (e.g., number of bits, location of bits) to specify, among other things, the operation to be performed (e.g., opcode) and the operand(s) on which that operation is to be performed and/or other data field(s) (e.g., mask). Some instruction formats are further broken down through the definition of instruction templates (or sub-formats). For example, the instruction templates of a given instruction format may be defined to have different subsets of the instruction format's fields (the included fields are typically in the same order, but at least some have different bit positions because there are less fields included) and/or defined to have a given field interpreted differently. Thus, each instruction of an ISA is expressed using a given instruction format (and, if defined, in a given one of the instruction templates of that instruction format) and includes fields for specifying the operation and the operands. For example, an example ADD instruction has a specific opcode and an instruction format that includes an opcode field to specify that opcode and operand fields to select operands (source1/destination and source2); and an occurrence of this ADD instruction in an instruction stream will have specific contents in the operand fields that select specific operands. In addition, though the description below is made in the context of x86 ISA, it is within the knowledge of one skilled in the art to apply the teachings of the present disclosure in another ISA.

### Example Instruction Formats

Examples of the instruction(s) described herein may be embodied in different formats. Additionally, example systems, architectures, and pipelines are detailed below. Examples of the instruction(s) may be executed on such systems, architectures, and pipelines, but are not limited to those detailed.

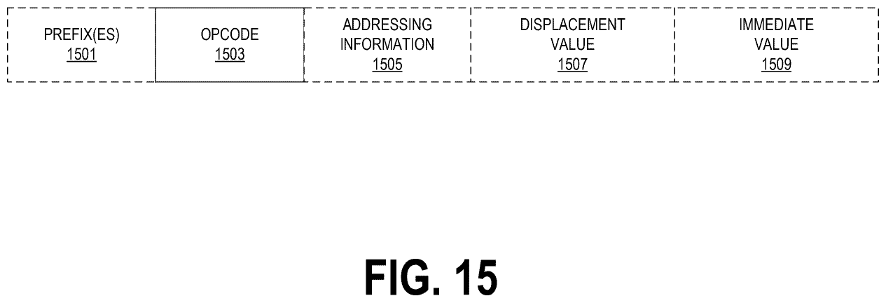

FIG. 15 illustrates examples of an instruction format. As illustrated, an instruction may include multiple components including, but not limited to, one or more fields for: one or more prefixes, an opcode, addressing information (e.g., register identifiers, memory addressing information, etc.), a displacement value, and/or an immediate value. Note that some instructions utilize some or all the fields of the format whereas others may only use the field for the opcode 1503. In some examples, the order illustrated is the order in which these fields are to be encoded, however, it should be appreciated that in other examples these fields may be encoded in a different order, combined, etc.

The prefix(es) f 1501, when used, modifies an instruction. In some examples, one or more prefixes are used to repeat string instructions (e.g., 0xF0, 0xF2, 0xF3, etc.), to provide section overrides (e.g., 0x2E, 0x36, 0x3E, 0x26, 0x64, 0x65, 0x2E, 0x3E, etc.), to perform bus lock operations, and/or to change operand (e.g., 0x66) and address sizes (e.g., 0x67). Certain instructions require a mandatory prefix (e.g., 0x66, 0xF2, 0xF3, etc.). Certain of these prefixes may be considered “legacy” prefixes. Other prefixes, one or more examples of which are detailed herein, indicate, and/or provide further capability, such as specifying particular registers, etc. The other prefixes typically follow the “legacy”prefixes.

The opcode field 1503 is used to at least partially define the operation to be performed upon a decoding of the instruction. In some examples, a primary opcode encoded in the opcode field 1503 is one, two, or three bytes in length. In other examples, a primary opcode can be a different length. An additional 3-bit opcode field is sometimes encoded in another field. The addressing information field 1505 is used to address one or more operands of the instruction, such as a location in memory or one or more registers.

### Graphics Execution Units

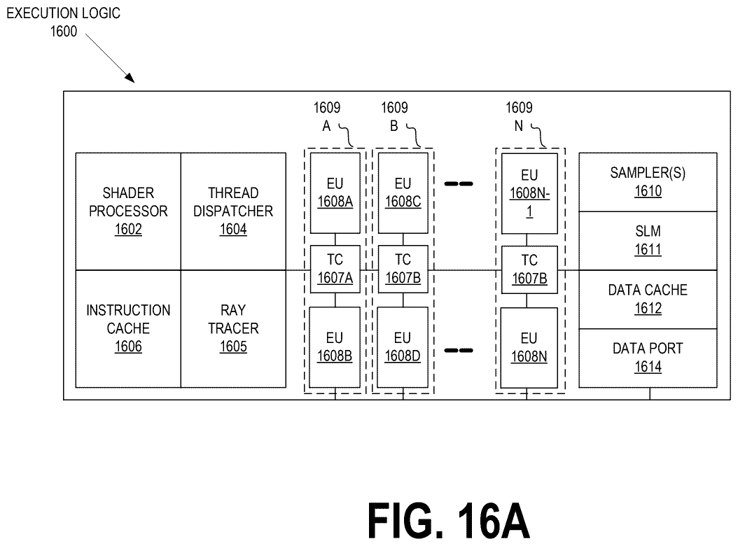

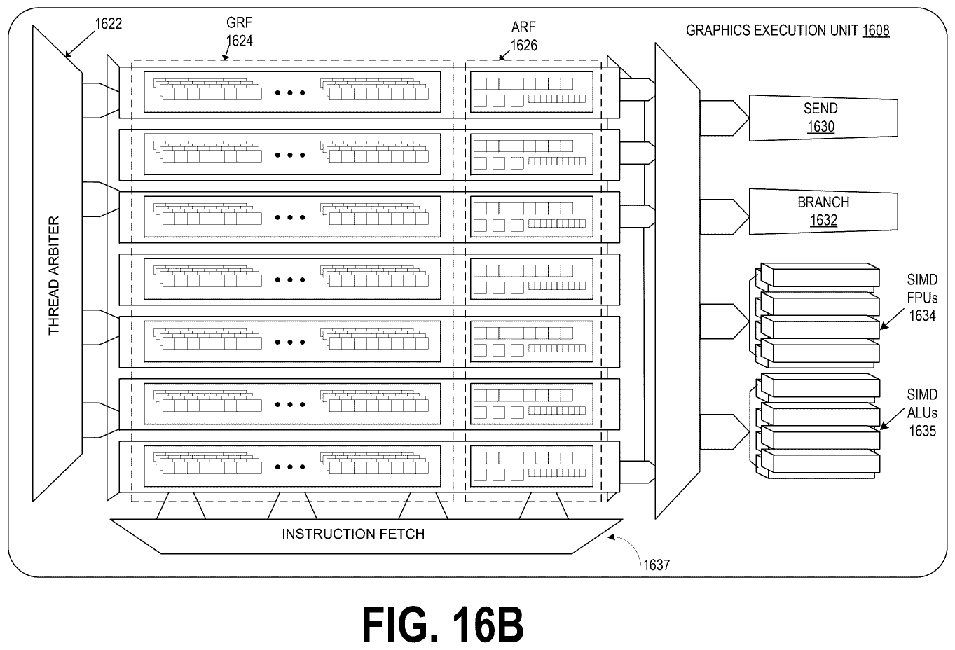

FIGS. 16A-16B illustrate thread execution logic 1600 including an array of processing elements employed in a graphics processor core according to examples described herein. Elements of FIGS. 16A-16B having the same reference numbers (or names) as the elements of any other figure herein can operate or function in any manner similar to that described elsewhere herein, but are not limited to such. FIG. 16A is representative of an execution unit within a general-purpose graphics processor, while FIG. 16B is representative of an execution unit that may be used within a compute accelerator.

As illustrated in FIG. 16A, in some examples thread execution logic 1600 includes a shader processor 1602, a thread dispatcher 1604, instruction cache 1606, a scalable execution unit array including a plurality of execution units 1608A-1608N, a sampler 1610, shared local memory 1611, a data cache 1612, and a data port 1614. In some examples the scalable execution unit array can dynamically scale by enabling or disabling one or more execution units (e.g., any of execution units 1608A, 1608B, 1608C, 1608D, through 1608N-1 and 1608N) based on the computational requirements of a workload. In some examples the included components are interconnected via an interconnect fabric that links to each of the components. In some examples, thread execution logic 1600 includes one or more connections to memory, such as system memory or cache memory, through one or more of instruction cache 1606, data port 1614, sampler 1610, and execution units 1608A-1608N. In some examples, each execution unit (e.g. 1608A) is a stand-alone programmable general-purpose computational unit that is capable of executing multiple simultaneous hardware threads while processing multiple data elements in parallel for each thread. In various examples, the array of execution units 1608A-1608N is scalable to include any number individual execution units.

In some examples, the execution units 1608A-1608N are primarily used to execute shader programs. A shader processor 1602 can process the various shader programs and dispatch execution threads associated with the shader programs via a thread dispatcher 1604. In some examples the thread dispatcher includes logic to arbitrate thread initiation requests from the graphics and media pipelines and instantiate the requested threads on one or more execution units in the execution units 1608A-1608N. For example, a geometry pipeline can dispatch vertex, tessellation, or geometry shaders to the thread execution logic for processing. In some examples, thread dispatcher 1604 can also process runtime thread spawning requests from the executing shader programs.

In some examples, the execution units 1608A-1608N support an instruction set that includes native support for many standard 3D graphics shader instructions, such that shader programs from graphics libraries (e.g., Direct 3D and OpenGL) are executed with a minimal translation. The execution units support vertex and geometry processing (e.g., vertex programs, geometry programs, vertex shaders), pixel processing (e.g., pixel shaders, fragment shaders) and general-purpose processing (e.g., compute and media shaders). Each of the execution units 1608A-1608N is capable of multi-issue single instruction multiple data (SIMD) execution and multi-threaded operation enables an efficient execution environment in the face of higher latency memory accesses. Each hardware thread within each execution unit has a dedicated high-bandwidth register file and associated independent thread-state. Execution is multi-issue per clock to pipelines capable of integer, single and double precision floating point operations, SIMD branch capability, logical operations, transcendental operations, and other miscellaneous operations. While waiting for data from memory or one of the shared functions, dependency logic within the execution units 1608A-1608N causes a waiting thread to sleep until the requested data has been returned. While the waiting thread is sleeping, hardware resources may be devoted to processing other threads. For example, during a delay associated with a vertex shader operation, an execution unit can perform operations for a pixel shader, fragment shader, or another type of shader program, including a different vertex shader. Various examples can apply to use execution by use of Single Instruction Multiple Thread (SIMT) as an alternate to use of SIMD or in addition to use of SIMD. Reference to a SIMD core or operation can apply also to SIMT or apply to SIMD in combination with SIMT.

Each execution unit in execution units 1608A-1608N operates on arrays of data elements. The number of data elements is the “execution size,” or the number of channels for the instruction. An execution channel is a logical unit of execution for data element access, masking, and flow control within instructions. The number of channels may be independent of the number of physical Arithmetic Logic Units (ALUs) or Floating Point Units (FPUs) for a particular graphics processor. In some examples, execution units 1608A-1608N support integer and floating-point data types.

The execution unit instruction set includes SIMD instructions. The various data elements can be stored as a packed data type in a register and the execution unit will process the various elements based on the data size of the elements. For example, when operating on a 256-bit wide vector, the 256 bits of the vector are stored in a register and the execution unit operates on the vector as four separate 64-bit packed data elements (Quad-Word (QW) size data elements), eight separate 32-bit packed data elements (Double Word (DW) size data elements), sixteen separate 16-bit packed data elements (Word (W) size data elements), or thirty-two separate 8-bit data elements (byte (B) size data elements). However, different vector widths and register sizes are possible.

In some examples one or more execution units can be combined into a fused graphics execution unit 1609A-1609N having thread control logic (1607A-1607N) that is common to the fused EUs. Multiple EUs can be fused into an EU group. Each EU in the fused EU group can be configured to execute a separate SIMD hardware thread. The number of EUs in a fused EU group can vary according to examples. Additionally, various SIMD widths can be performed per-EU, including but not limited to SIMD8, SIMD16, and SIMD32. Each fused graphics execution unit 1609A-1609N includes at least two execution units. For example, fused execution unit 1609A includes a first EU 1608A, second EU 1608B, and thread control logic 1607A that is common to the first EU 1608A and the second EU 1608B. The thread control logic 1607A controls threads executed on the fused graphics execution unit 1609A, allowing each EU within the fused execution units 1609A-1609N to execute using a common instruction pointer register.

One or more internal instruction caches (e.g., 1606) are included in the thread execution logic 1600 to cache thread instructions for the execution units. In some examples, one or more data caches (e.g., 1612) are included to cache thread data during thread execution. Threads executing on the thread execution logic 1600 can also store explicitly managed data in the shared local memory 1611. In some examples, a sampler 1610 is included to provide texture sampling for 3D operations and media sampling for media operations. In some examples, sampler 1610 includes specialized texture or media sampling functionality to process texture or media data during the sampling process before providing the sampled data to an execution unit.

During execution, the graphics and media pipelines send thread initiation requests to thread execution logic 1600 via thread spawning and dispatch logic. Once a group of geometric objects has been processed and rasterized into pixel data, pixel processor logic (e.g., pixel shader logic, fragment shader logic, etc.) within the shader processor 1602 is invoked to further compute output information and cause results to be written to output surfaces (e.g., color buffers, depth buffers, stencil buffers, etc.). In some examples, a pixel shader or fragment shader calculates the values of the various vertex attributes that are to be interpolated across the rasterized object. In some examples, pixel processor logic within the shader processor 1602 then executes an application programming interface (API)-supplied pixel or fragment shader program. To execute the shader program, the shader processor 1602 dispatches threads to an execution unit (e.g., 1608A) via thread dispatcher 1604. In some examples, shader processor 1602 uses texture sampling logic in the sampler 1610 to access texture data in texture maps stored in memory. Arithmetic operations on the texture data and the input geometry data compute pixel color data for each geometric fragment, or discards one or more pixels from further processing.

In some examples, the data port 1614 provides a memory access mechanism for the thread execution logic 1600 to output processed data to memory for further processing on a graphics processor output pipeline. In some examples, the data port 1614 includes or couples to one or more cache memories (e.g., data cache 1612) to cache data for memory access via the data port.

In some examples, the execution logic 1600 can also include a ray tracer 1605 that can provide ray tracing acceleration functionality. The ray tracer 1605 can support a ray tracing instruction set that includes instructions/functions for ray generation.

FIG. 16B illustrates exemplary internal details of an execution unit 1608, according to examples. A graphics execution unit 1608 can include an instruction fetch unit 1637, a general register file array (GRF) 1624, an architectural register file array (ARF) 1626, a thread arbiter 1622, a send unit 1630, a branch unit 1632, a set of SIMD floating point units (FPUs) 1634, and in some examples a set of dedicated integer SIMD ALUs 1635. The GRF 1624 and ARF 1626 includes the set of general register files and architecture register files associated with each simultaneous hardware thread that may be active in the graphics execution unit 1608. In some examples, per thread architectural state is maintained in the ARF 1626, while data used during thread execution is stored in the GRF 1624. The execution state of each thread, including the instruction pointers for each thread, can be held in thread-specific registers in the ARF 1626.

In some examples the graphics execution unit 1608 has an architecture that is a combination of Simultaneous Multi-Threading (SMT) and fine-grained Interleaved Multi-Threading (IMT). The architecture has a modular configuration that can be fine-tuned at design time based on a target number of simultaneous threads and number of registers per execution unit, where execution unit resources are divided across logic used to execute multiple simultaneous threads. The number of logical threads that may be executed by the graphics execution unit 1608 is not limited to the number of hardware threads, and multiple logical threads can be assigned to each hardware thread.

In some examples, the graphics execution unit 1608 can co-issue multiple instructions, which may each be different instructions. The thread arbiter 1622 of the graphics execution unit thread 1608 can dispatch the instructions to one of the send unit 1630, branch unit 1632, or SIMD FPU(s) 1634 for execution. Each execution thread can access 128 general-purpose registers within the GRF 1624, where each register can store 32 bytes, accessible as a SIMD 8-element vector of 32-bit data elements. In some examples, each execution unit thread has access to 4 Kbytes within the GRF 1624, although examples are not so limited, and greater or fewer register resources may be provided in other examples. In some examples the graphics execution unit 1608 is partitioned into seven hardware threads that can independently perform computational operations, although the number of threads per execution unit can also vary according to examples. For example, in some examples up to 16 hardware threads are supported. In an example in which seven threads may access 4 Kbytes, the GRF 1624 can store a total of 28 Kbytes. Where 16 threads may access 4 Kbytes, the GRF 1624 can store a total of 64 Kbytes. Flexible addressing modes can permit registers to be addressed together to build effectively wider registers or to represent strided rectangular block data structures.

In some examples, memory operations, sampler operations, and other longer-latency system communications are dispatched via “send” instructions that are executed by the message passing send unit 1630. In some examples, branch instructions are dispatched to a dedicated branch unit 1632 to facilitate SIMD divergence and eventual convergence.

In some examples the graphics execution unit 1608 includes one or more SIMD FPU(s) 1634 to perform floating-point operations. In some examples, the FPU(s) 1634 also support integer computation. In some examples the FPU(s) 1634 can SIMD execute up to M number of 32-bit floating-point (or integer) operations, or SIMD execute up to 2M 16-bit integer or 16-bit floating-point operations. In some examples, at least one of the FPU(s) provides extended math capability to support high-throughput transcendental math functions and double precision 64-bit floating-point. In some examples, a set of 8-bit integer SIMD ALUs 1635 are also present, and may be specifically optimized to perform operations associated with machine learning computations.

In some examples, arrays of multiple instances of the graphics execution unit 1608 can be instantiated in a graphics sub-core grouping (e.g., a sub-slice). For scalability, product architects can choose the exact number of execution units per sub-core grouping. In some examples the execution unit 1608 can execute instructions across a plurality of execution channels. In a further example, each thread executed on the graphics execution unit 1608 is executed on a different channel.

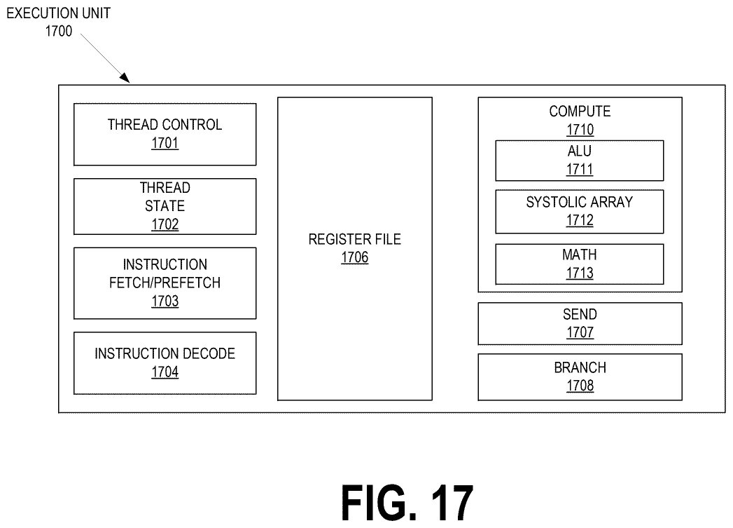

FIG. 17 illustrates an additional execution unit 1700, according to an example. In some examples, the execution unit 1700 includes a thread control unit 1701, a thread state unit 1702, an instruction fetch/prefetch unit 1703, and an instruction decode unit 1704. The execution unit 1700 additionally includes a register file 1706 that stores registers that can be assigned to hardware threads within the execution unit. The execution unit 1700 additionally includes a send unit 1707 and a branch unit 1708. In some examples, the send unit 1707 and branch unit 1708 can operate similarly as the send unit 1630 and a branch unit 1632 of the graphics execution unit 1608 of FIG. 16B.

The execution unit 1700 also includes a compute unit 1710 that includes multiple different types of functional units. In some examples the compute unit 1710 includes an ALU unit 1711 that includes an array of arithmetic logic units. The ALU unit 1711 can be configured to perform 64-bit, 32-bit, and 16-bit integer and floating point operations. Integer and floating point operations may be performed simultaneously. The compute unit 1710 can also include a systolic array 1712, and a math unit 1713. The systolic array 1712 includes a W wide and D deep network of data processing units that can be used to perform vector or other data-parallel operations in a systolic manner. In some examples the systolic array 1712 can be configured to perform matrix operations, such as matrix dot product operations. In some examples the systolic array 1712 support 16-bit floating point operations, as well as 8-bit and 4-bit integer operations. In some examples the systolic array 1712 can be configured to accelerate machine learning operations. In such examples, the systolic array 1712 can be configured with support for the bfloat 16-bit floating point format. In some examples, a math unit 1713 can be included to perform a specific subset of mathematical operations in an efficient and lower-power manner than the ALU unit 1711. The math unit 1713 can include a variant of math logic that may be found in shared function logic of a graphics processing engine provided by other examples. In some examples the math unit 1713 can be configured to perform 32-bit and 64-bit floating point operations.

The thread control unit 1701 includes logic to control the execution of threads within the execution unit. The thread control unit 1701 can include thread arbitration logic to start, stop, and preempt execution of threads within the execution unit 1700. The thread state unit 1702 can be used to store thread state for threads assigned to execute on the execution unit 1700. Storing the thread state within the execution unit 1700 enables the rapid pre-emption of threads when those threads become blocked or idle. The instruction fetch/prefetch unit 1703 can fetch instructions from an instruction cache of higher level execution logic (e.g., instruction cache 1606 as in FIG. 16A). The instruction fetch/prefetch unit 1703 can also issue prefetch requests for instructions to be loaded into the instruction cache based on an analysis of currently executing threads. The instruction decode unit 1704 can be used to decode instructions to be executed by the compute units. In some examples, the instruction decode unit 1704 can be used as a secondary decoder to decode complex instructions into constituent micro-operations.

The execution unit 1700 additionally includes a register file 1706 that can be used by hardware threads executing on the execution unit 1700. Registers in the register file 1706 can be divided across the logic used to execute multiple simultaneous threads within the compute unit 1710 of the execution unit 1700. The number of logical threads that may be executed by the execution unit 1700 is not limited to the number of hardware threads, and multiple logical threads can be assigned to each hardware thread. The size of the register file 1706 can vary across examples based on the number of supported hardware threads. In some examples, register renaming may be used to dynamically allocate registers to hardware threads.

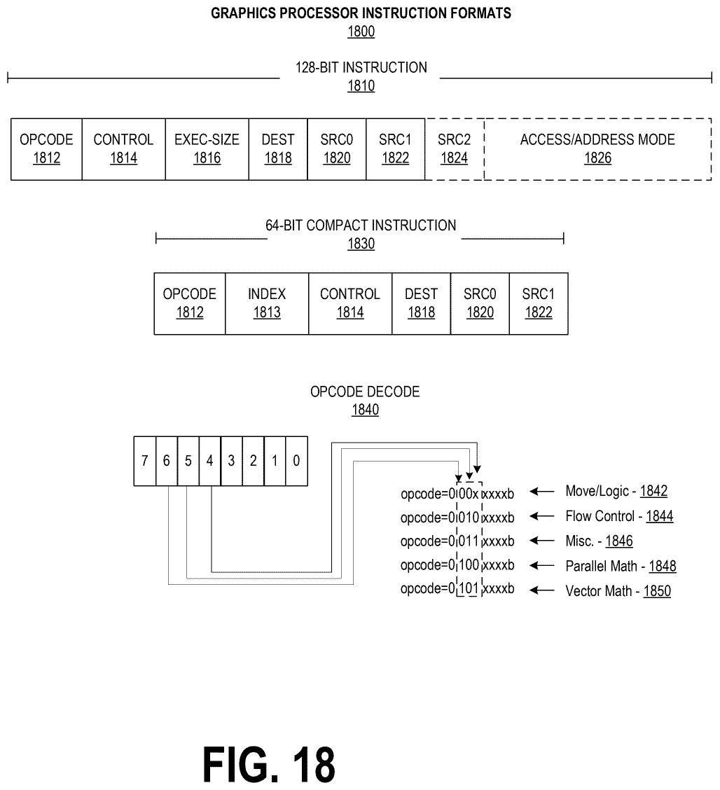

FIG. 18 is a block diagram illustrating a graphics processor instruction formats 1800 according to some examples. In one or more examples, the graphics processor execution units support an instruction set having instructions in multiple formats. The solid lined boxes illustrate the components that are generally included in an execution unit instruction, while the dashed lines include components that are optional or that are only included in a sub-set of the instructions. In some examples, instruction format 1800 described and illustrated are macroinstructions, in that they are instructions supplied to the execution unit, as opposed to micro-operations resulting from instruction decode once the instruction is processed.

In some examples, the graphics processor execution units natively support instructions in a 128-bit instruction format 1810. A 64-bit compacted instruction format 1830 is available for some instructions based on the selected instruction, instruction options, and number of operands. The native 128-bit instruction format 1810 provides access to all instruction options, while some options and operations are restricted in the 64-bit compacted format 1830. The native instructions available in the 64-bit compacted format 1830 vary by example. In some examples, the instruction is compacted in part using a set of index values in an index field 1813. The execution unit hardware references a set of compaction tables based on the index values and uses the compaction table outputs to reconstruct a native instruction in the 128-bit instruction format 1810. Other sizes and formats of instruction can be used.

For each format, instruction opcode 1812 defines the operation that the execution unit is to perform. The execution units execute each instruction in parallel across the multiple data elements of each operand. For example, in response to an add instruction the execution unit performs a simultaneous add operation across each color channel representing a texture element or picture element. By default, the execution unit performs each instruction across all data channels of the operands. In some examples, instruction control field 1814 enables control over certain execution options, such as channels selection (e.g., predication) and data channel order (e.g., swizzle). For instructions in the 128-bit instruction format 1810 an exec-size field 1816 limits the number of data channels that will be executed in parallel. In some examples, exec-size field 1816 is not available for use in the 64-bit compact instruction format 1830.

Some execution unit instructions have up to three operands including two source operands, src0 1820, src1 1822, and one destination 1818. In some examples, the execution units support dual destination instructions, where one of the destinations is implied. Data manipulation instructions can have a third source operand (e.g., SRC2 1824), where the instruction opcode 1812 determines the number of source operands. An instruction's last source operand can be an immediate (e.g., hard-coded) value passed with the instruction.

In some examples, the 128-bit instruction format 1810 includes an access/address mode field 1826 specifying, for example, whether direct register addressing mode or indirect register addressing mode is used. When direct register addressing mode is used, the register address of one or more operands is directly provided by bits in the instruction.

In some examples, the 128-bit instruction format 1810 includes an access/address mode field 1826, which specifies an address mode and/or an access mode for the instruction. In some examples the access mode is used to define a data access alignment for the instruction. Some examples support access modes including a 16-byte aligned access mode and a 1-byte aligned access mode, where the byte alignment of the access mode determines the access alignment of the instruction operands. For example, when in a first mode, the instruction may use byte-aligned addressing for source and destination operands and when in a second mode, the instruction may use 16-byte-aligned addressing for all source and destination operands.

In some examples, the address mode portion of the access/address mode field 1826 determines whether the instruction is to use direct or indirect addressing. When direct register addressing mode is used bits in the instruction directly provide the register address of one or more operands. When indirect register addressing mode is used, the register address of one or more operands may be computed based on an address register value and an address immediate field in the instruction.

In some examples instructions are grouped based on opcode 1812 bit-fields to simplify Opcode decode 1840. For an 8-bit opcode, bits 4, 5, and 6 allow the execution unit to determine the type of opcode. The precise opcode grouping shown is merely an example. In some examples, a move and logic opcode group 1842 includes data movement and logic instructions (e.g., move (mov), compare (cmp)). In some examples, move and logic opcode group 1842 shares the five most significant bits (MSB), where move (mov) instructions are in the form of 0000xxxxb and logic instructions are in the form of 0001xxxxb. A flow control instruction group 1844 (e.g., call, jump (jmp)) includes instructions in the form of 0010xxxxb (e.g., 0x20). A miscellaneous instruction group 1846 includes a mix of instructions, including synchronization instructions (e.g., wait, send) in the form of 0011xxxxb (e.g., 0x30). A parallel math instruction group 1848 includes component-wise arithmetic instructions (e.g., add, multiply (mul)) in the form of 0100xxxxb (e.g., 0x40). The parallel math instruction group 1848 performs the arithmetic operations in parallel across data channels. The vector math group 1850 includes arithmetic instructions (e.g., dp4) in the form of 0101xxxxb (e.g., 0x50). The vector math group performs arithmetic such as dot product calculations on vector operands. The illustrated opcode decode 1840, in some examples, can be used to determine which portion of an execution unit will be used to execute a decoded instruction. For example, some instructions may be designated as systolic instructions that will be performed by a systolic array. Other instructions, such as ray-tracing instructions (not shown) can be routed to a ray-tracing core or ray-tracing logic within a slice or partition of execution logic.

### Graphics Pipeline

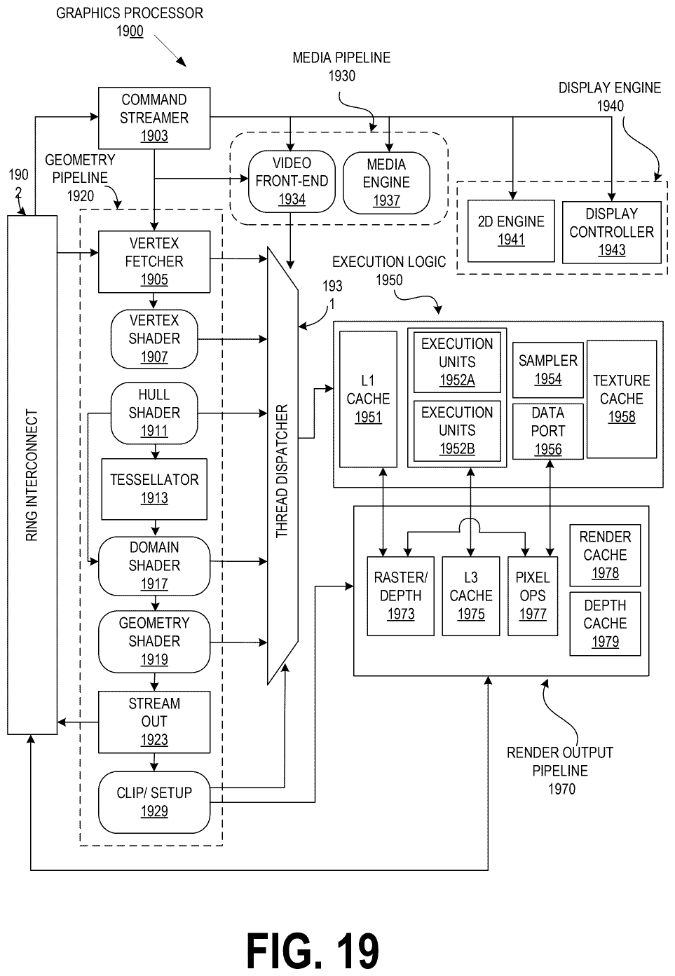

FIG. 19 is a block diagram of another example of a graphics processor 1900. Elements of FIG. 19 having the same reference numbers (or names) as the elements of any other figure herein can operate or function in any manner similar to that described elsewhere herein, but are not limited to such.

In some examples, graphics processor 1900 includes a geometry pipeline 1920, a media pipeline 1930, a display engine 1940, thread execution logic 1950, and a render output pipeline 1970. In some examples, graphics processor 1900 is a graphics processor within a multi-core processing system that includes one or more general-purpose processing cores. The graphics processor is controlled by register writes to one or more control registers (not shown) or via commands issued to graphics processor 1900 via a ring interconnect 1902. In some examples, ring interconnect 1902 couples graphics processor 1900 to other processing components, such as other graphics processors or general-purpose processors. Commands from ring interconnect 1902 are interpreted by a command streamer 1903, which supplies instructions to individual components of the geometry pipeline 1920 or the media pipeline 1930.

In some examples, command streamer 1903 directs the operation of a vertex fetcher 1905 that reads vertex data from memory and executes vertex-processing commands provided by command streamer 1903. In some examples, vertex fetcher 1905 provides vertex data to a vertex shader 1907, which performs coordinate space transformation and lighting operations to each vertex. In some examples, vertex fetcher 1905 and vertex shader 1907 execute vertex-processing instructions by dispatching execution threads to execution units 1952A-1952B via a thread dispatcher 1931.

In some examples, execution units 1952A-1952B are an array of vector processors having an instruction set for performing graphics and media operations. In some examples, execution units 1952A-1952B have an attached L1 cache 1951 that is specific for each array or shared between the arrays. The cache can be configured as a data cache, an instruction cache, or a single cache that is partitioned to contain data and instructions in different partitions.

In some examples, geometry pipeline 1920 includes tessellation components to perform hardware-accelerated tessellation of 3D objects. In some examples, a programmable hull shader 1911 configures the tessellation operations. A programmable domain shader 1917 provides back-end evaluation of tessellation output. A tessellator 1913 operates at the direction of hull shader 1911 and contains special purpose logic to generate a set of detailed geometric objects based on a coarse geometric model that is provided as input to geometry pipeline 1920. In some examples, if tessellation is not used, tessellation components (e.g., hull shader 1911, tessellator 1913, and domain shader 1917) can be bypassed.

In some examples, complete geometric objects can be processed by a geometry shader 1919 via one or more threads dispatched to execution units 1952A-1952B, or can proceed directly to the clipper 1929. In some examples, the geometry shader operates on entire geometric objects, rather than vertices or patches of vertices as in previous stages of the graphics pipeline. If the tessellation is disabled the geometry shader 1919 receives input from the vertex shader 1907. In some examples, geometry shader 1919 is programmable by a geometry shader program to perform geometry tessellation if the tessellation units are disabled.

Before rasterization, a clipper 1929 processes vertex data. The clipper 1929 may be a fixed function clipper or a programmable clipper having clipping and geometry shader functions. In some examples, a rasterizer and depth test component 1973 in the render output pipeline 1970 dispatches pixel shaders to convert the geometric objects into per pixel representations. In some examples, pixel shader logic is included in thread execution logic 1950. In some examples, an application can bypass the rasterizer and depth test component 1973 and access un-rasterized vertex data via a stream out unit 1923.

The graphics processor 1900 has an interconnect bus, interconnect fabric, or some other interconnect mechanism that allows data and message passing amongst the major components of the processor. In some examples, execution units 1952A-1952B and associated logic units (e.g., L1 cache 1951, sampler 1954, texture cache 1958, etc.) interconnect via a data port 1956 to perform memory access and communicate with render output pipeline components of the processor. In some examples, sampler 1954, caches 1951, 1958 and execution units 1952A-1952B each have separate memory access paths. In some examples the texture cache 1958 can also be configured as a sampler cache.

In some examples, render output pipeline 1970 contains a rasterizer and depth test component 1973 that converts vertex-based objects into an associated pixel-based representation. In some examples, the rasterizer logic includes a windower/masker unit to perform fixed function triangle and line rasterization. An associated render cache 1978 and depth cache 1979 are also available in some examples. A pixel operations component 1977 performs pixel-based operations on the data, though in some instances, pixel operations associated with 2D operations (e.g. bit block image transfers with blending) are performed by the 2D engine 1941, or substituted at display time by the display controller 1943 using overlay display planes. In some examples, a shared L3 cache 1975 is available to all graphics components, allowing the sharing of data without the use of main system memory.

In some examples, media pipeline 1930 includes a media engine 1937 and a video front-end 1934. In some examples, video front-end 1934 receives pipeline commands from the command streamer 1903. In some examples, media pipeline 1930 includes a separate command streamer. In some examples, video front-end 1934 processes media commands before sending the command to the media engine 1937. In some examples, media engine 1937 includes thread spawning functionality to spawn threads for dispatch to thread execution logic 1950 via thread dispatcher 1931.

In some examples, graphics processor 1900 includes a display engine 1940. In some examples, display engine 1940 is external to graphics processor 1900 and couples with the graphics processor via the ring interconnect 1902, or some other interconnect bus or fabric. In some examples, display engine 1940 includes a 2D engine 1941 and a display controller 1943. In some examples, display engine 1940 contains special purpose logic capable of operating independently of the 3D pipeline. In some examples, display controller 1943 couples with a display device (not shown), which may be a system integrated display device, as in a laptop computer, or an external display device attached via a display device connector.

In some examples, the geometry pipeline 1920 and media pipeline 1930 are configurable to perform operations based on multiple graphics and media programming interfaces and are not specific to any one application programming interface (API). In some examples, driver software for the graphics processor translates API calls that are specific to a particular graphics or media library into commands that can be processed by the graphics processor. In some examples, support is provided for the Open Graphics Library (OpenGL), Open Computing Language (OpenCL), and/or Vulkan graphics and compute API, all from the Khronos Group. In some examples, support may also be provided for the Direct3D library from the Microsoft Corporation. In some examples, a combination of these libraries may be supported. Support may also be provided for the Open Source Computer Vision Library (OpenCV). A future API with a compatible 3D pipeline would also be supported if a mapping can be made from the pipeline of the future API to the pipeline of the graphics processor.

### Graphics Pipeline Programming

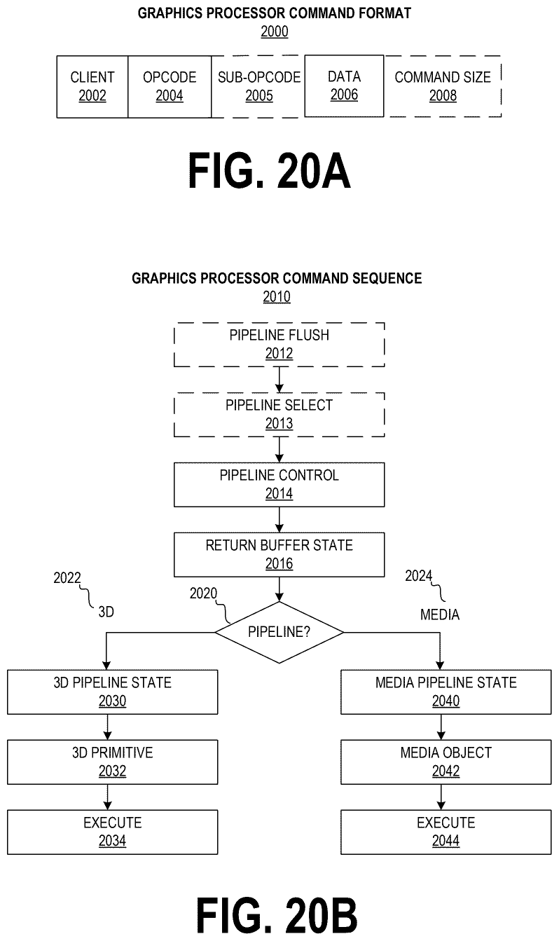

FIG. 20A is a block diagram illustrating a graphics processor command format 2000 according to some examples. FIG. 20B is a block diagram illustrating a graphics processor command sequence 2010 according to an example. The solid lined boxes in FIG. 20A illustrate the components that are generally included in a graphics command while the dashed lines include components that are optional or that are only included in a sub-set of the graphics commands. The graphics processor command format 2000 of FIG. 20A includes data fields to identify a client 2002, a command operation code (opcode) 2004, and data 2006 for the command. A sub-opcode 2005 and a command size 2008 are also included in some commands.

In some examples, client 2002 specifies the client unit of the graphics device that processes the command data. In some examples, a graphics processor command parser examines the client field of each command to condition the further processing of the command and route the command data to the appropriate client unit. In some examples, the graphics processor client units include a memory interface unit, a render unit, a 2D unit, a 3D unit, and a media unit. Each client unit has a corresponding processing pipeline that processes the commands. Once the command is received by the client unit, the client unit reads the opcode 2004 and, if present, sub-opcode 2005 to determine the operation to perform. The client unit performs the command using information in data field 2006. For some commands an explicit command size 2008 is expected to specify the size of the command. In some examples, the command parser automatically determines the size of at least some of the commands based on the command opcode. In some examples commands are aligned via multiples of a double word. Other command formats can be used.

The flow diagram in FIG. 20B illustrates a graphics processor command sequence 2010. In some examples, software or firmware of a data processing system that features an example of a graphics processor uses a version of the command sequence shown to set up, execute, and terminate a set of graphics operations. A sample command sequence is shown and described for purposes of example only as examples are not limited to these specific commands or to this command sequence. Moreover, the commands may be issued as batch of commands in a command sequence, such that the graphics processor will process the sequence of commands in at least partially concurrence.

In some examples, the graphics processor command sequence 2010 may begin with a pipeline flush command 2012 to cause any active graphics pipeline to complete the currently pending commands for the pipeline. In some examples, the 3D pipeline 2022 and the media pipeline 2024 do not operate concurrently. The pipeline flush is performed to cause the active graphics pipeline to complete any pending commands. In response to a pipeline flush, the command parser for the graphics processor will pause command processing until the active drawing engines complete pending operations and the relevant read caches are invalidated. Optionally, any data in the render cache that is marked ‘dirty’ can be flushed to memory. In some examples, pipeline flush command 2012 can be used for pipeline synchronization or before placing the graphics processor into a low power state.

In some examples, a pipeline select command 2013 is used when a command sequence requires the graphics processor to explicitly switch between pipelines. In some examples, a pipeline select command 2013 is required only once within an execution context before issuing pipeline commands unless the context is to issue commands for both pipelines. In some examples, a pipeline flush command 2012 is required immediately before a pipeline switch via the pipeline select command 2013.

In some examples, a pipeline control command 2014 configures a graphics pipeline for operation and is used to program the 3D pipeline 2022 and the media pipeline 2024. In some examples, pipeline control command 2014 configures the pipeline state for the active pipeline. In some examples, the pipeline control command 2014 is used for pipeline synchronization and to clear data from one or more cache memories within the active pipeline before processing a batch of commands.

In some examples, return buffer state commands 2016 are used to configure a set of return buffers for the respective pipelines to write data. Some pipeline operations require the allocation, selection, or configuration of one or more return buffers into which the operations write intermediate data during processing. In some examples, the graphics processor also uses one or more return buffers to store output data and to perform cross thread communication. In some examples, the return buffer state includes selecting the size and number of return buffers to use for a set of pipeline operations.

The remaining commands in the command sequence differ based on the active pipeline for operations. Based on a pipeline determination 2020, the command sequence is tailored to the 3D pipeline 2022 beginning with the 3D pipeline state 2030 or the media pipeline 2024 beginning at the media pipeline state 2040.

The commands to configure the 3D pipeline state 2030 include 3D state setting commands for vertex buffer state, vertex element state, constant color state, depth buffer state, and other state variables that are to be configured before 3D primitive commands are processed. The values of these commands are determined at least in part based on the particular 3D API in use. In some examples, 3D pipeline state 2030 commands are also able to selectively disable or bypass certain pipeline elements if those elements will not be used.

In some examples, 3D primitive 2032 command is used to submit 3D primitives to be processed by the 3D pipeline. Commands and associated parameters that are passed to the graphics processor via the 3D primitive 2032 command are forwarded to the vertex fetch function in the graphics pipeline. The vertex fetch function uses the 3D primitive 2032 command data to generate vertex data structures. The vertex data structures are stored in one or more return buffers. In some examples, 3D primitive 2032 command is used to perform vertex operations on 3D primitives via vertex shaders. To process vertex shaders, 3D pipeline 2022 dispatches shader execution threads to graphics processor execution units.

In some examples, 3D pipeline 2022 is triggered via an execute 2034 command or event. In some examples, a register write triggers command execution. In some examples execution is triggered via a ‘go’ or ‘kick’ command in the command sequence. In some examples, command execution is triggered using a pipeline synchronization command to flush the command sequence through the graphics pipeline. The 3D pipeline will perform geometry processing for the 3D primitives. Once operations are complete, the resulting geometric objects are rasterized and the pixel engine colors the resulting pixels. Additional commands to control pixel shading and pixel back end operations may also be included for those operations.

In some examples, the graphics processor command sequence 2010 follows the media pipeline 2024 path when performing media operations. In general, the specific use and manner of programming for the media pipeline 2024 depends on the media or compute operations to be performed. Specific media decode operations may be offloaded to the media pipeline during media decode. In some examples, the media pipeline can also be bypassed and media decode can be performed in whole or in part using resources provided by one or more general-purpose processing cores. In some examples, the media pipeline also includes elements for general-purpose graphics processor unit (GPGPU) operations, where the graphics processor is used to perform SIMD vector operations using computational shader programs that are not explicitly related to the rendering of graphics primitives.

In some examples, media pipeline 2024 is configured in a similar manner as the 3D pipeline 2022. A set of commands to configure the media pipeline state 2040 are dispatched or placed into a command queue before the media object commands 2042. In some examples, commands for the media pipeline state 2040 include data to configure the media pipeline elements that will be used to process the media objects. This includes data to configure the video decode and video encode logic within the media pipeline, such as encode or decode format. In some examples, commands for the media pipeline state 2040 also support the use of one or more pointers to “indirect”state elements that contain a batch of state settings.

In some examples, media object commands 2042 supply pointers to media objects for processing by the media pipeline. The media objects include memory buffers containing video data to be processed. In some examples, all media pipeline states must be valid before issuing a media object command 2042. Once the pipeline state is configured and media object commands 2042 are queued, the media pipeline 2024 is triggered via an execute command 2044 or an equivalent execute event (e.g., register write). Output from media pipeline 2024 may then be post processed by operations provided by the 3D pipeline 2022 or the media pipeline 2024. In some examples, GPGPU operations are configured and executed in a similar manner as media operations.

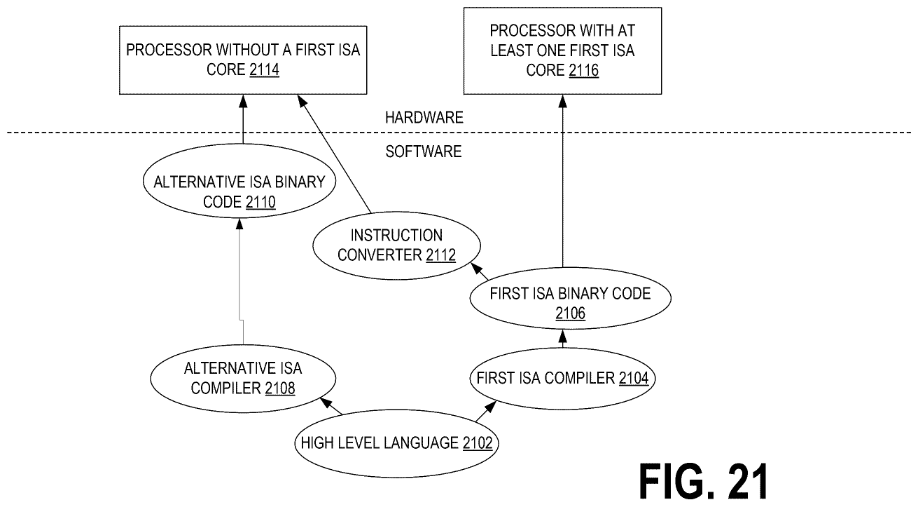

FIG. 21 is a block diagram illustrating the use of a software instruction converter to convert binary instructions in a source ISA to binary instructions in a target ISA according to examples. In the illustrated example, the instruction converter is a software instruction converter, although alternatively the instruction converter may be implemented in software, firmware, hardware, or various combinations thereof. FIG. 21 shows a program in a high-level language 2102 may be compiled using a first ISA compiler 2104 to generate first ISA binary code 2106 that may be natively executed by a processor with at least one first ISA core 2116. The processor with at least one first ISA core 2116 represents any processor that can perform substantially the same functions as an Intel® processor with at least one first ISA core by compatibly executing or otherwise processing (1) a substantial portion of the first ISA or (2) object code versions of applications or other software targeted to run on an Intel processor with at least one first ISA core, in order to achieve substantially the same result as a processor with at least one first ISA core. The first ISA compiler 2104 represents a compiler that is operable to generate first ISA binary code 2106 (e.g., object code) that can, with or without additional linkage processing, be executed on the processor with at least one first ISA core 2116. Similarly, FIG. 21 shows the program in the high-level language 2102 may be compiled using an alternative ISA compiler 2108 to generate alternative ISA binary code 2110 that may be natively executed by a processor without a first ISA core 2114. The instruction converter 2112 is used to convert the first ISA binary code 2106 into code that may be natively executed by the processor without a first ISA core 2114. This converted code is not necessarily to be the same as the alternative ISA binary code 2110; however, the converted code will accomplish the general operation and be made up of instructions from the alternative ISA. Thus, the instruction converter 2112 represents software, firmware, hardware, or a combination thereof that, through emulation, simulation or any other process, allows a processor or other electronic device that does not have a first ISA processor or core to execute the first ISA binary code 2106.

### Ip Core Implementations

One or more aspects of at least some examples may be implemented by representative code stored on a machine-readable medium which represents and/or defines logic within an integrated circuit such as a processor. For example, the machine-readable medium may include instructions which represent various logic within the processor. When read by a machine, the instructions may cause the machine to fabricate the logic to perform the techniques described herein. Such representations, known as “IP cores,” are reusable units of logic for an integrated circuit that may be stored on a tangible, machine-readable medium as a hardware model that describes the structure of the integrated circuit. The hardware model may be supplied to various customers or manufacturing facilities, which load the hardware model on fabrication machines that manufacture the integrated circuit. The integrated circuit may be fabricated such that the circuit performs operations described in association with any of the examples described herein

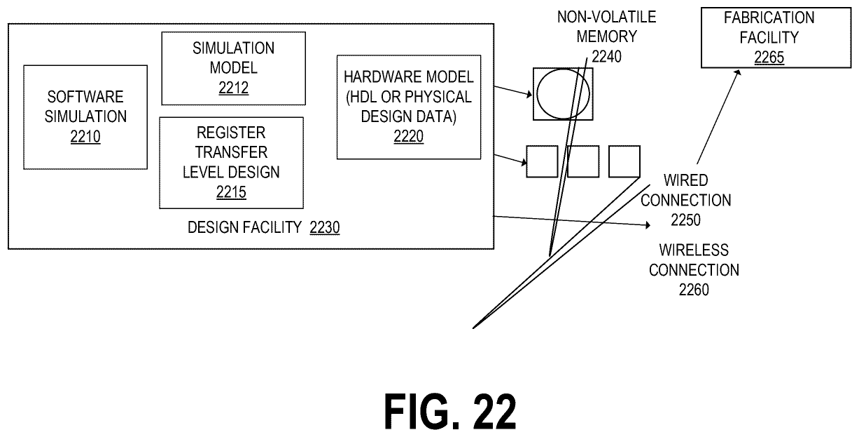

FIG. 22 is a block diagram illustrating an IP core development system 2200 that may be used to manufacture an integrated circuit to perform operations according to some examples. The IP core development system 2200 may be used to generate modular, re-usable designs that can be incorporated into a larger design or used to construct an entire integrated circuit (e.g., an SOC integrated circuit). A design facility 2230 can generate a software simulation 2210 of an IP core design in a high-level programming language (e.g., C/C++). The software simulation 2210 can be used to design, test, and verify the behavior of the IP core using a simulation model 2212. The simulation model 2212 may include functional, behavioral, and/or timing simulations. A register transfer level (RTL) design 2215 can then be created or synthesized from the simulation model 2212. The RTL design 2215 is an abstraction of the behavior of the integrated circuit that models the flow of digital signals between hardware registers, including the associated logic performed using the modeled digital signals. In addition to an RTL design 2215, lower-level designs at the logic level or transistor level may also be created, designed, or synthesized. Thus, the particular details of the initial design and simulation may vary.

The RTL design 2215 or equivalent may be further synthesized by the design facility into a hardware model 2220, which may be in a hardware description language (HDL), or some other representation of physical design data. The HDL may be further simulated or tested to verify the IP core design. The IP core design can be stored for delivery to a fabrication facility 2265 using non-volatile memory 2240 (e.g., hard disk, flash memory, or any non-volatile storage medium). Alternatively, the IP core design may be transmitted (e.g., via the Internet) over a wired connection 2250 or wireless connection 2260. The fabrication facility 2265 may then fabricate an integrated circuit that is based at least in part on the IP core design. The fabricated integrated circuit can be configured to perform operations in accordance with at least some examples described herein.

Illustrative examples of the technologies disclosed herein are provided below. An embodiment of the technologies may include any one or more, and any compatible combination of, the examples described below.

Example 1 is an apparatus that includes a core supply rail, a memory supply rail, and a core. The core includes a core logic circuit coupled to the core supply rail, a memory circuit, and a power multiplexer (mux) coupled to the core supply rail, memory supply rail and the memory circuit, wherein the power mux is configured to couple a selected one of the core supply rail and memory supply rail to the memory circuit.

Example 2 includes the subject matter of example 1, and wherein the memory supply rail is to provide a static minimum memory operating voltage.

Example 3 includes the subject matter of any of examples 1-2, and wherein the core supply rail is to provide a voltage that can go below the static minimum memory operating voltage.

Example 4 includes the subject matter of any of examples 1-3, and wherein the power mux includes a first variable resistance leg coupled between the core supply rail and the memory circuit and a second variable resistance leg coupled between the memory supply rail and the memory circuit.

Example 5 includes the subject matter of any of examples 1-4, and wherein the first variable resistance leg includes at least one switch to select the first variable resistance leg when it is to be active.

Example 6 includes the subject matter of any of examples 1-5, and wherein the first variable resistance leg includes at least one variable resistance transistor coupled in series with the at least one switch to control a resistance of the first variable resistance leg.

Example 7 includes the subject matter of any of examples 1-6, and wherein the at least one variable resistance transistor is coupled to a controllable voltage source to control a gate bias of the at least one variable resistance transistor.

Example 8 includes the subject matter of any of examples 1-7, and wherein the controllable voltage source comprises a resistor ladder circuit.

Example 9 includes the subject matter of any of examples 1-8, and wherein the at least one variable resistance transistor comprises a plurality of parallel coupled transistors with a multiplicity of controllable activation combinations to provide different resistance values for the plurality of parallel coupled transistors.

Example 10 includes the subject matter of any of examples 1-9, and comprising a power control circuit coupled to the power mux to control the first and second variable resistance legs based on a voltage difference between the core supply rail and the memory supply rail.

Example 11 includes the subject matter of any of examples 1-10, and wherein the power control circuit is part of the core.

Example 12 is an apparatus that includes a core supply rail, a cache supply rail, a core logic circuit coupled to the core supply rail, a cache circuit, a cache control circuit coupled to the cache circuit, and a first power multiplexer (mux) coupled to the core supply rail, to the cache supply rail and to the cache control circuit. The first power mux is configured to couple a first selected one of the core supply rail and cache supply rail to the cache control circuit.

Example 13 includes the subject matter of example 12, and wherein the first power mux includes a first variable resistance leg coupled between the core supply rail and the cache control circuit and a second variable resistance leg coupled between the cache supply rail and the cache control circuit.

Example 14 includes the subject matter of any of examples 12-13, and wherein the first variable resistance leg includes at least one switch to select the first variable resistance leg when it is to be active.

Example 15 includes the subject matter of any of examples 12-14, and wherein the first variable resistance leg includes at least one variable resistance transistor coupled in series with the at least one switch to control the resistance of the first variable resistance leg.

Example 16 includes the subject matter of any of examples 12-15, and comprising a power control circuit coupled to the first power mux to control the first and second variable resistance legs based on a voltage difference between the core supply rail and the cache supply rail.

Example 17 includes the subject matter of any of examples 12-16, and comprising a second power mux coupled to the core supply rail, cache supply rail and the cache circuit, wherein the second power mux is configured to couple a second selected one of the core supply rail and cache supply rail to the cache circuit.

Example 18 includes the subject matter of any of examples 12-17, and wherein the power control circuit is to control the second power mux to couple the cache supply rail to the cache circuit based on the core supply rail having a lower voltage than the cache supply rail.

Example 19 includes the subject matter of any of examples 12-18, and wherein the power control circuit is to control the first power mux to couple the cache supply rail to the cache control circuit in response to the core logic circuit to go into a power reduction mode.

Example 20 is a processor that includes a first core, a second core, a cache supply rail, a first power mux, and a second power mux. The first core includes a first core supply rail, a first core logic circuit coupled to the first core supply rail, and a first cache circuit. The second core includes a second core supply rail, a second core logic circuit coupled to the second core supply rail, and a second cache circuit. The first power mux is coupled to the first core supply rail, to the cache supply rail and to the first cache circuit. The first power mux is configured to couple a first selected one of the first core supply rail and the cache supply rail to the first cache circuit. The second power mux is coupled to the second core supply rail, to the cache supply rail and to the second cache circuit. The second power mux is configured to couple a second selected one of the second core supply rail and the cache supply rail to the second cache circuit.

Example 21 includes the subject matter of example 20, and comprising a third power mux coupled to the first core supply rail, to the cache supply rail and to a first cache control circuit that is coupled to the first cache circuit, wherein the third power mux is configured to couple a second selected one of the first core supply rail and the cache supply rail to the first cache control circuit.

Example 22 includes the subject matter of any of examples 20-21, and comprising a fourth power mux coupled to the second core supply rail, to the cache supply rail and to a second cache control circuit that is coupled to the second cache circuit, wherein the fourth power mux is configured to couple a second selected one of the second core supply rail and the cache supply rail to the second cache control circuit.

Example 23 includes the subject matter of any of examples 20-22, and comprising a first power control circuit to control the first power mux to couple the cache supply rail to the first cache circuit based on the first core supply rail having a lower voltage than the cache supply rail.

Example 24 includes the subject matter of any of examples 20-23, and wherein the first power control circuit is to control the third power mux to couple the cache supply rail to the first cache control circuit in response to the first core logic circuit to go into a power reduction mode.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, it may be implemented on a single die, multiple dies (dielets, chiplets), one or more dies in a common package, or one or more dies in multiple packages. Along these lines, some of these blocks may be located separately on different dies or together on two or more different dies.

Program code may be applied to input information to perform the functions described herein and generate output information. The output information may be applied to one or more output devices, in known fashion. For purposes of this application, a processing system includes any system that has a processor, such as, for example, a digital signal processor (DSP), a microcontroller, an application specific integrated circuit (ASIC), a field programmable gate array (FPGA), a microprocessor, or any combination thereof.

The program code may be implemented in a high-level procedural or object-oriented programming language to communicate with a processing system. The program code may also be implemented in assembly or machine language, if desired. In fact, the mechanisms described herein are not limited in scope to any particular programming language. In any case, the language may be a compiled or interpreted language.

Examples of the mechanisms disclosed herein may be implemented in hardware, software, firmware, or a combination of such implementation approaches. Examples may be implemented as computer programs or program code executing on programmable systems comprising at least one processor, a storage system (including volatile and non-volatile memory and/or storage elements), at least one input device, and at least one output device.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, examples also include non-transitory, tangible machine-readable media containing instructions or containing design data, such as Hardware Description Language (HDL), which defines structures, circuits, apparatuses, processors and/or system features described herein. Such examples may also be referred to as program products.

In some cases, an instruction converter may be used to convert an instruction from a source instruction set architecture to a target instruction set architecture. For example, the instruction converter may translate (e.g., using static binary translation, dynamic binary translation including dynamic compilation), morph, emulate, or otherwise convert an instruction to one or more other instructions to be processed by the core. The instruction converter may be implemented in software, hardware, firmware, or a combination thereof. The instruction converter may be on processor, off processor, or part on and part off processor.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a core supply rail;
a memory supply rail; and
a core including:
a core logic circuit coupled to the core supply rail,
a memory circuit, and
a power multiplexer (mux) coupled to the core supply rail, memory supply rail and the memory circuit, wherein the power mux is configured to couple a selected one of the core supply rail and memory supply rail to the memory circuit.

2. The apparatus of claim 1, wherein the memory supply rail is to provide a static minimum memory operating voltage.

3. The apparatus of claim 2, wherein the core supply rail is to provide a voltage that can go below the static minimum memory operating voltage.

4. The apparatus of claim 1, wherein the power mux includes a first variable resistance leg coupled between the core supply rail and the memory circuit and a second variable resistance leg coupled between the memory supply rail and the memory circuit.

5. The apparatus of claim 4, wherein the first variable resistance leg includes at least one switch to select the first variable resistance leg when it is to be active.

6. The apparatus of claim 5, wherein the first variable resistance leg includes at least one variable resistance transistor coupled in series with the at least one switch to control a resistance of the first variable resistance leg.

7. The apparatus of claim 6, wherein the at least one variable resistance transistor is coupled to a controllable voltage source to control a gate bias of the at least one variable resistance transistor.

8. The apparatus of claim 7, wherein the controllable voltage source comprises a resistor ladder circuit.

9. The apparatus of claim 6, wherein the at least one variable resistance transistor comprises a plurality of parallel coupled transistors with a multiplicity of controllable activation combinations to provide different resistance values for the plurality of parallel coupled transistors.

10. The apparatus of claim 4, comprising a power control circuit coupled to the power mux to control the first and second variable resistance legs based on a voltage difference between the core supply rail and the memory supply rail.

11. The apparatus of claim 10, wherein the power control circuit is part of the core.

12. An apparatus, comprising:
a core supply rail;
a cache supply rail;
a core logic circuit coupled to the core supply rail,
a cache circuit;
a cache control circuit coupled to the cache circuit, and
a first power multiplexer (mux) coupled to the core supply rail, cache supply rail and the cache control circuit, wherein the first power mux is configured to couple a first selected one of the core supply rail and cache supply rail to the cache control circuit.

13. The apparatus of claim 12, wherein the first power mux includes a first variable resistance leg coupled between the core supply rail and the cache control circuit and a second variable resistance leg coupled between the cache supply rail and the cache control circuit.

14. The apparatus of claim 13, wherein the first variable resistance leg includes at least one variable resistance transistor coupled in series with at least one switch to control the resistance of the first variable resistance leg.

15. The apparatus of claim 13, comprising a power control circuit coupled to the first power mux to control the first and second variable resistance legs based on a voltage difference between the core supply rail and the cache supply rail.

16. The apparatus of claim 15, comprising a second power mux coupled to the core supply rail, to the cache supply rail and to the cache circuit, wherein the second power mux is configured to couple a second selected one of the core supply rail and cache supply rail to the cache circuit.

17. The apparatus of claim 16, wherein the power control circuit is to control the second power mux to couple the cache supply rail to the cache circuit based on the core supply rail having a lower voltage than the cache supply rail.

18. The apparatus of claim 17, wherein the power control circuit is to control the first power mux to couple the cache supply rail to the cache control circuit in response to the core logic circuit to go into a power reduction mode.

19. A processor, comprising:
a first core with a first core supply rail, a first core logic circuit coupled to the first core supply rail, and a first cache circuit;
a second core with a second core supply rail, a second core logic circuit coupled to the second core supply rail, and a second cache circuit;
a cache supply rail;
a first power multiplexer (mux) coupled to the first core supply rail, to the cache supply rail and to the first cache circuit, wherein the first power mux is configured to couple a first selected one of the first core supply rail and the cache supply rail to the first cache circuit; and
a second power mux coupled to the second core supply rail, to the cache supply rail and to the second cache circuit, wherein the second power mux is configured to couple a second selected one of the second core supply rail and the cache supply rail to the second cache circuit.

20. The processor of claim 19, comprising a third power mux coupled to the first core supply rail, to the cache supply rail and to a first cache control circuit that is coupled to the first cache circuit, wherein the third power mux is configured to couple a second selected one of the first core supply rail and the cache supply rail to the first cache control circuit.
